(19) United States
(12) Patent Application Publication
(10) Pub. No.: US 2025/0338541 A1
(43) Pub. Date: Oct. 30, 2025

(54) INTEGRATED CIRCUIT DEVICE

(71) Applicant: Samsung Electronics Co., Ltd., Suwon-si (KR)

(72) Inventors: Hyunmin AHN, Suwon-si (KR); Soojin JEONG, Suwon-si (KR); Wookhyun KWON, Suwon-si (KR); Bumcheol KIM, Suwon-si (KR); Byounghak HONG, Suwon-si (KR)

(73) Assignee: Samsung Electronics Co., Ltd., Suwon-si (KR)

(21) Appl. No.: 18/988,158

(22) Filed: Dec. 19, 2024

(30) Foreign Application Priority Data
Apr. 29, 2024 (KR) 10-2024-0056769

(51) Int. Cl. H10D 30/00; H10D 30/43; H10D 30/67; H10D 62/10; H10D 62/13; H10D 84/83

(52) U.S. Cl. CPC H10D 30/509; H10D 30/43; H10D 30/502; H10D 30/6735; H10D 30/6757; H10D 62/121; H10D 62/151; H10D 84/832

(57) ABSTRACT

An integrated circuit device may include a nanosheet stack including a plurality of nanosheets, a gate line at least partially surrounding each of the plurality of nanosheets, the gate line including a main gate part and a sub-gate part, a source/drain region in contact with the plurality of nanosheets, and an inner insulating spacer between the sub-gate part and the source/drain region, wherein a first sidewall and a second sidewall each include a part recessed toward an inside of the inner insulating spacer, the first sidewall facing the source/drain and the second sidewall opposite to the first sidewall.

### CROSS-REFERENCE TO RELATED APPLICATION

This application claims priority under 35 U.S.C. § 119 to Korean Patent Application No. 10-2024-0056769, filed on Apr. 29, 2024, in the Korean Intellectual Property Office, the disclosure of which is incorporated by reference herein in its entirety.

### BACKGROUND

At least some inventive concepts relate to an integrated circuit device, for example to an integrated circuit device including an inner insulating spacer.

As miniaturization, multifunctionalization, and/or higher performance of electronic products are desired, higher capacity and higher integration of integrated circuit devices are sought after. Accordingly, it may advantageous to efficiently design wiring structures to achieve higher integration while improving functions and/or operating speeds of integrated circuit devices.

### SUMMARY

At least some inventive concepts relate to an integrated circuit device having improved performance and/or reliability.

According to some example embodiments of inventive concepts, an integrated circuit device may include a fin-type active region on a substrate and extending in a first horizontal direction; a nanosheet stack including a plurality of nanosheets, the nanosheets facing a fin upper surface of the fin-type active region and spaced apart from the fin upper surface; a gate line on the fin-type active region, the gate line least partially surrounding each of the plurality of nanosheets and extending in a second horizontal direction intersecting the first horizontal direction, the gate line including a main gate part and a sub-gate part, the main gate part on an upper surface of the nanosheet stack and the sub-gate part between the main gate part and the fin-type active region; a source/drain region on the fin-type active region, adjacent to the gate line, and in contact with the plurality of nanosheets; and an inner insulating spacer between the sub-gate part and the source/drain region, wherein the inner insulating spacer includes a first sub-part in contact with an adjacent nanosheet from among the plurality of nanosheets, and a second sub-part at least partially overlapping with the first sub-part in a vertical direction, and a first sidewall and a second sidewall of the inner insulating spacer each include a part that is recessed toward an inside of the inner insulating spacer, the first sidewall facing the source/drain and the second sidewall opposite to the first sidewall.

According some example embodiments of inventive concepts, d an integrated circuit device may include a fin-type active region on a substrate and extending in a first horizontal direction, a channel region on the fin-type active region; a gate line at least partially surrounding the channel region on the fin-type active region and extending in a second horizontal direction that intersects the first horizontal direction; a source/drain region on the fin-type active region, adjacent to the gate line, and in contact with the channel region; and an inner insulating spacer between the gate line and the source/drain region and including a first sidewall, the first sidewall in contact with the source/drain region, wherein the inner insulating spacer includes two first sub-parts vertically apart from each other and a second sub-part vertically between the two first sub-parts, the first sidewall of the inner insulating spacer includes a part recessed toward the inside of the inner insulating spacer, and each of the two first sub-parts includes a part whose vertical thickness decreases as each first sub-part is closer to the gate line.

According to some example embodiments of inventive concepts, an integrated circuit device may include a fin-type active region on a substrate and extending in a first horizontal direction, a nanosheet stack including a plurality of nanosheets, at least one the nanosheets facing a fin upper surface of the fin-type active region and spaced apart from the fin upper surface; a gate line on the fin-type active region, at least partially surrounding each of the plurality of nanosheets, and extending in a second horizontal direction that intersects the first horizontal direction, the gate line including a main gate part on a upper surface of the nanosheet stack and a sub-gate part between the main gate part and the fin-type active region; a source/drain region on the fin-type active region, adjacent to the gate line, and in contact with the plurality of nanosheets; and an inner insulating spacer between the sub-gate part and the source/drain region, wherein the inner insulating spacer includes two first sub-parts vertically apart from each other, and a second sub-part vertically between the two first sub-parts, the two first sub-parts comprise silicon nitride, the second sub-part comprises silicon oxide, a first sidewall and second sidewall of the inner insulating spacer each include a part that is recessed toward the inside of the inner insulating spacer, the first sidewall in contact with the source/drain and the second sidewall opposite to the first sidewall, and a distance between interfaces of each of the two first sub-parts with respect to the second sub-part increases as each first sub-part is closer to the gate line.

### BRIEF DESCRIPTION OF THE DRAWINGS

Example embodiments will be more clearly understood from the following detailed description taken in conjunction with the accompanying drawings in which:

FIG. 1 is a plan layout diagram for explaining an integrated circuit device according to some example embodiments;

FIGS. 2A to 2C are cross-sectional views for explaining integrated circuit devices according to some example embodiments;

FIG. 3 is an enlarged cross-sectional view for explaining an integrated circuit device according to some example embodiments;

FIG. 4 is an enlarged cross-sectional view for explaining an integrated circuit device according to some example embodiments;

FIGS. 5 and 6 are enlarged cross-sectional views for explaining an integrated circuit device according to some example embodiments;

FIG. 7 is a cross-sectional view for explaining an integrated circuit device according to some example embodiments;

FIG. 8 is an enlarged cross-sectional view for explaining an integrated circuit device according to some example embodiments;

FIG. 9 is an enlarged cross-sectional view for explaining an integrated circuit device according to some example embodiments;

FIG. 10 is an enlarged cross-sectional view for explaining an integrated circuit device according to some example embodiments; and

FIGS. 11 to 23 are cross-sectional views illustrating a process order to explain methods of manufacturing an integrated circuit device in accordance with some example embodiments.

### DETAILED DESCRIPTION

For the sake of clarity, parts that are not connected with the description will be omitted, and the same elements or equivalents are referred to by the same reference numerals throughout the specification. Further, since, for example, sizes and/or thicknesses of constituent members shown in the accompanying drawings may be arbitrarily given for better understanding and ease of description, example embodiments are not limited to, for example, the illustrated sizes and thicknesses. In the drawings, the thickness of layers, films, panels, regions, etc., for example, are exaggerated for clarity. In the drawings, for better understanding and ease of description, sizes and/or thicknesses of some layers, areas, and the like may be excessively displayed.

It will be understood that when an element or layer is referred to as being “over,” “above,” “on,” “below,” “under,” “beneath,” another element or layer, it can be directly over, above, on, below, under, beneath to the other element or layer or intervening elements or layers may be present. In contrast, when an element is referred to as being “directly over,” “directly above,” “directly on,” “directly below,” “directly under,” “directly beneath,” another element or layer, there are no intervening elements or layers present.

It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof.

In addition, unless explicitly described to the contrary, the word “comprises”, and variations such as “comprises” or “comprising”, will be understood to imply the inclusion of stated elements but not the exclusion of any other elements.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

Singular expressions may include plural expressions unless the context clearly indicates otherwise. Terms, such as “include” or “has” may be interpreted as adding features, numbers, steps, operations, components, parts, or combinations thereof described in the specification. Singular expressions may include plural expressions unless the context clearly indicates otherwise.

It will be understood that when an element or layer is referred to as being, for example, “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Hereinafter, at least some example embodiments of inventive concepts will be described in detail with reference to the accompanying drawings. The same reference numerals are used for the same components in the drawings, and redundant descriptions thereof are omitted.

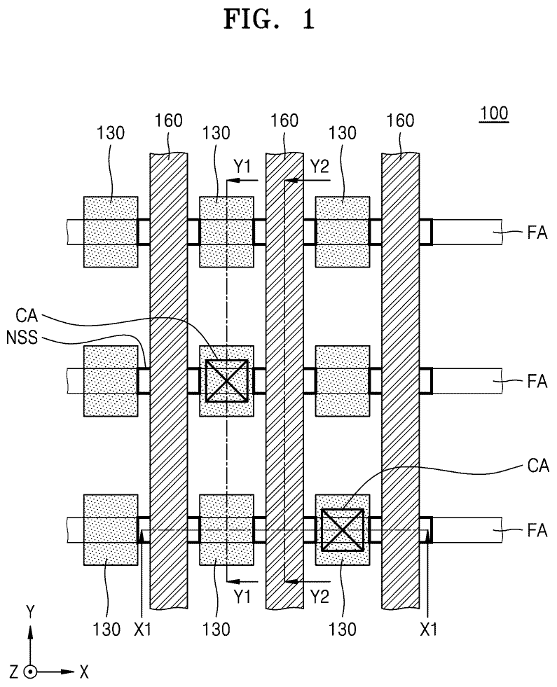

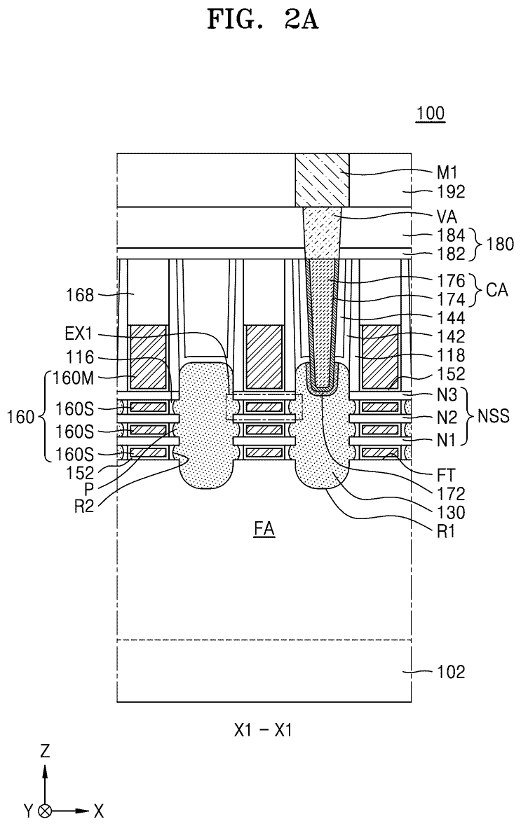

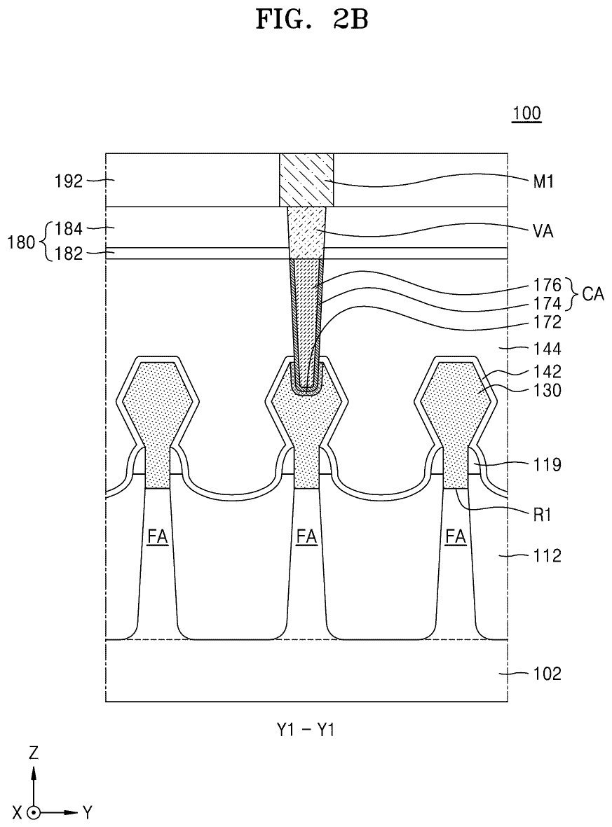

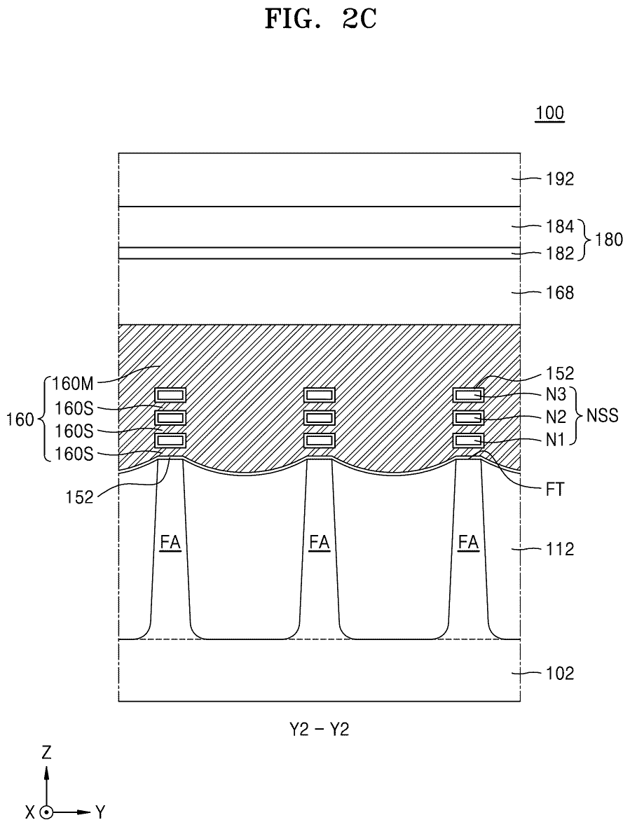

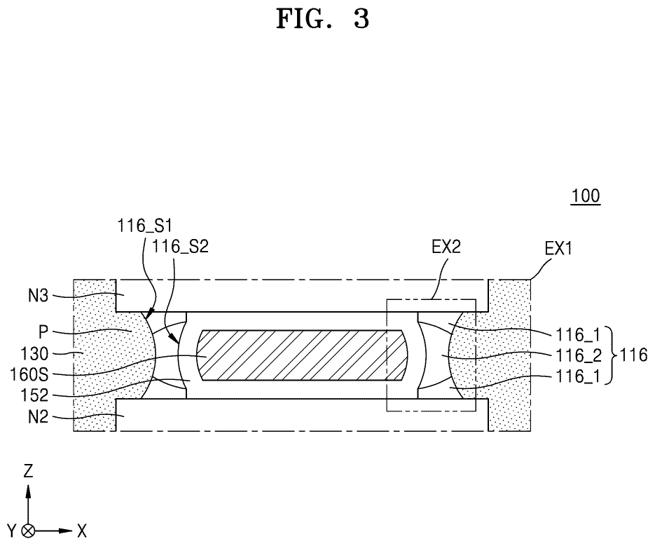

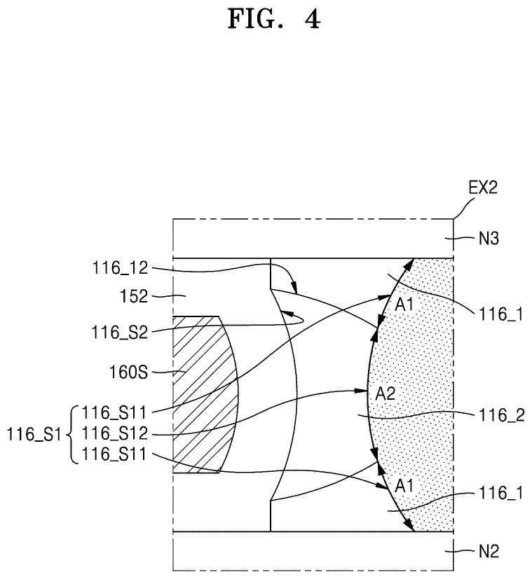

FIG. 1 is a plan layout diagram of illustrating an integrated circuit device 100 according to some example embodiments. FIGS. 2A to 2C are cross-sectional views for explaining integrated circuit devices 100 according to some example embodiments. FIG. 3 is an enlarged cross-sectional view for explaining an integrated circuit device 100 according to some example embodiments. FIG. 4 is an enlarged cross-sectional view for explaining an integrated circuit device 100 according to some example embodiments. For example, FIGS. 2A to 2C are cross-sectional views taken along lines X1-X1, Y1-Y1, and Y2-Y2 of FIG. 1, respectively. FIG. 3 is an enlarged cross-sectional view of a region EX1 of FIG. 2A. FIG. 4 is an enlarged cross-sectional view of a region EX2 of FIG. 3.

An integrated circuit device 100 including, for example, a field effect transistor having an active area in the shape of a nanowire or nanosheet and a gate-all-around structure including a gate surrounding (for example, at least partially surrounding) the active area is described with reference to FIGS. 1, 2A to 2C, 3, and 4.

The integrated circuit device 100 may include a substrate 102 and a plurality of fin-type active regions FA protruding from the substrate 102. A plurality of fin-type active regions FA may extend lengthwise in the first horizontal direction (X direction) on the substrate 102 and may extend parallel to each other.

The substrate 102 may include one or more semiconductors, such as, for example, Si or Ge, or compound semiconductors, such as, for example, SiGe, SiC, GaAs, InAs, InGaAs, or InP, but example embodiments are not limited thereto. The terms “SiGe”, “SiC”, “GaAs”, “InAs”, “InGaAs”, and “InP” used herein refer to materials composed of elements included in each term, and are not chemical formulae representing a stoichiometric relationship. The substrate 102 may include a conductive region, for example, an impurity-doped well or an impurity-doped structure, but example embodiments are not limited thereto.

A device isolation layer 112 may be arranged in a trench limiting (for example, defined or at least partially defined by) a plurality of fin-type active regions FA. The device isolation layer 112 may cover a part or at least a part of the sidewalls of each of the plurality of fin-type active regions FA and may extend from the substrate 102 in the vertical direction (Z direction). The device isolation layer 112 may, for example, include a silicon oxide layer, but example embodiments are not limited thereto. The device isolation layer 112 may include a material, for example, having an etch selectivity different from that of the substrate 102.

As illustrated in FIGS. 1, 2A, and 2C, a plurality of gate lines 160 may be on the plurality of fin-type active regions FA. Each of a plurality of gate lines 160 may extend lengthwise in a second horizontal direction (Y direction) crossing (for example, intersecting or intersecting with) the first horizontal direction (X direction). In regions where the plurality of fin-type active regions FA and the plurality of gate lines 160 cross (for example, overlap with) each other, a plurality of nanosheet stacks NSS may be on a fin upper surface FT of each of the plurality of fin-type active regions FA. Each of the plurality of nanosheet stacks NSS may include at least one nanosheet facing (for example, having at least one surface facing toward) the fin upper surface FT at a position spaced apart from the fin upper surface FT of each of the fin-type active regions FA in the vertical direction (Z direction). In the present specification, the term “nanosheet” may refer to a conductive structure having a cross-section perpendicular or substantially perpendicular to a direction in which a current flows. It should be understood that the nanosheet includes nanowires.

As illustrated in FIGS. 2A and 2C, each of the plurality of nanosheet stacks NSS may include a first nanosheet N1, a second nanosheet N2, and a third nanosheet N3 overlapping or at least partially overlapping with each other in the vertical direction (Z direction) on each of the fin-type active regions FA. The first nanosheet N1, the second nanosheet N2, and the third nanosheet N3 may have different vertical distances (Z-direction distances) from the fin upper surface FT of each of the fin-type active regions FA. Each of the plurality of gate lines 160 may surround or at least partially surround the first nanosheet N1, the second nanosheet N2, and the third nanosheet N3 included in the nanosheet stack NSS and overlapping with each other in the vertical direction (Z direction).

Although FIG. 1 illustrates a case in which a planar shape of the nanosheet stack NSS is approximately rectangular, example embodiments are not limited thereto. The nanosheet stacks NSS may have various planar or substantially planar shapes according to a planar or substantially planar shape of each of the fin-type active regions FA and/or gate lines 160. In some example embodiments, each of a plurality of nanosheet stacks NSS and each of a plurality of gate lines 160 are on a fin-type active region FA, and each of a plurality of nanosheet stacks NSS is, for example, arranged in a line in a first horizontal direction (X direction) on a fin-type active region FA. However, the number of nanosheet stacks NSS and the number of gate lines 160 placed on one fin-type active regions FA are not particularly limited.

Each of the first nanosheet N1, the second nanosheet N2, and the third nanosheet N3 included in the nanosheet stack NSS may function or be configured to function as a channel region. According to some example embodiments, each of the first nanosheet N1, the second nanosheet N2, and the third nanosheet N3 may have a thickness selected from a range of, for example, about 4 nm to about 6 nm, but is not limited thereto. Here, the thickness of each of the first nanosheet N1, the second nanosheet N2, and the third nanosheet N3 means a magnitude in the vertical direction (Z direction). According to some example embodiments, the first nanosheet N1, the second nanosheet N2, and the third nanosheet N3 may have the same or substantially the same thickness in the vertical direction (Z direction). According to some example embodiments, at least some of the first nanosheet N1, the second nanosheet N2, and the third nanosheet N3 may have different or substantially different thicknesses in the vertical direction (Z direction). According to some example embodiments, each of the first nanosheet N1, the second nanosheet N2, and the third nanosheet N3 included in the nanosheet stacks NSS may include, for example, a Si layer, a SiGe layer, or a combination thereof, but example embodiments are not limited thereto.

As illustrated in FIG. 2A, the first nanosheet N1, the second nanosheet N2, and the third nanosheet N3 included in one nanosheet stack NSS may have the same or similar sizes in the first horizontal direction (X direction). In some example embodiments, unlike illustrated in FIG. 2A, at least some of the first nanosheet N1, the second nanosheet N2, and the third nanosheet N3 included in one nanosheet stack NSS may have different sizes in the first horizontal direction (X direction). In FIG. 2A, a case where each of the plurality of nanosheet stacks NSS includes three nanosheets has been illustrated, but example embodiments are not limited to those illustrated. For example, the nanosheet stack NSS may include, for example, at least one nanosheet, and the number of nanosheets constituting the nanosheet stack NSS is not particularly limited.

As illustrated in FIGS. 2A and 2C, the plurality of gate lines 160 may include a main gate part 160M and a plurality of sub-gate parts 160S, respectively. The main gate part 160M may extend lengthwise in a second horizontal direction (Y direction) and cover or at least partially cover the upper surface of the nanosheet stack NSS. The plurality of sub-gate parts 160S may be connected (for example, integrally connected) to the main gate part 160M, and each of the plurality of sub-gate parts 160S may be respectively arranged between the first nanosheet N1 and the second nanosheet N2, between the second nanosheet N2 and the third nanosheet N3, and between the first nanosheet N1 and each of the fin-type active regions FA. In the vertical direction (Z direction), a thickness of each of the plurality of sub-gate parts 160S may be less than a thickness of the main gate part 160M.

Each of the plurality of gate lines 160 may include a metal, for example, a metal nitride, a metal carbide, and/or a combination thereof, but example embodiments are not limited thereto. The metal may be selected from, for example, Ti, W, Ru, Nb, Mo, Hf, Ni, Co, Pt, Yb, Tb, Dy, Er, and Pd. The metal nitride may be selected from, for example, TiN and TaN. The metal carbide may be, for example, TiAlC. However, the material(s) constituting the plurality of gate lines 160 is not limited to the above examples.

As illustrated in FIGS. 2A and 2B, a plurality of first recesses (or recessed areas) R1 may be formed on (for example, defined or at least partially defined by) the fin-type active regions FA, respectively. A vertical level of the lowest surface of each of the plurality of first recesses R1 may be lower than a vertical level of the fin upper surface FT of each of the fin-type active regions FA.

As illustrated in FIGS. 2A and 2B, a plurality of source/drain regions 130 may be arranged in the plurality of first recesses R1, respectively. Each of the plurality of source/drain regions 130 may be arranged at a position adjacent to at least one gate line 160 selected from among the plurality of gate lines 160. The plurality of source/drain regions 130 may have surfaces being, for example, in contact (for example, direct contact) with the first nanosheet N1, the second nanosheet N2, and/or the third nanosheet N3 included in the adjacent nanosheet stack NSS, respectively. The plurality of source/drain regions 130 may be, for example in contact (for example, direct contact) with the first nanosheet N1, the second nanosheet N2, and/or the third nanosheet N3 included in the adjacent nanosheet stack NSS, respectively. However, example embodiments are not limited thereto.

As illustrated in FIG. 2A, the source/drain regions 130 may include a plurality of protrusions P protruding toward the plurality of sub-gate parts 160S, respectively. The plurality of protrusions P may be arranged within a plurality of second recesses (or recessed areas) R2, respectively. The plurality of protrusions P may overlap or at least partially overlap with the plurality of sub-gate parts 160S in the first horizontal direction (X-direction), respectively. The plurality of protrusions P may respectively overlap or at least partially overlap with the first nanosheet N1, the second nanosheet N2, and the third nanosheet N3 included in the nanosheet stack NSS in the vertical direction (Z direction). The plurality of protrusions P may be respectively arranged between the first nanosheet N1 and the second nanosheet N2, between the second nanosheet N2 and the third nanosheet N3 included in the nanosheet stack NSS, and between the first nanosheet N1 and the fin-type active regions FA.

A gate dielectric layer 152 may be arranged between the nanosheet stack NSS and the gate line 160. According to some example embodiments, the gate dielectric layer 152 may have, for example, a stacked structure of or including an interface dielectric layer and a high dielectric layer. The interface dielectric layer may include, for example, a low dielectric material layer having a dielectric constant of about 9 or less, for example, a silicon oxide layer, a silicon oxynitride layer, or a combination thereof, but example embodiments are not limited thereto. According to some example embodiments, the interface dielectric layer may be omitted. The high dielectric layer may be made of, for example, a material having a higher dielectric constant than that of a silicon oxide layer. For example, the high dielectric layer may have a dielectric constant of about 10 to about 25, but example embodiments are not limited thereto. The high dielectric layer may be made of hafnium oxide, but is not limited thereto.

For example, the gate dielectric layer 152 may include hafnium oxide. For example, the gate dielectric layer 152 may include a material different from those of a first sub-part 116_1 and a second sub-part 116_2 of the inner insulating spacer 116.

As illustrated in FIGS. 2A and 2Can upper surface of each of the gate dielectric layer 152 and the gate line 160 may be covered or at least partially covered with a capping insulating pattern 168. The capping insulating pattern 168 may include, for example, a silicon nitride layer, but example embodiments are not limited thereto.

Both sidewalls of each of the gate line 160 and the capping insulating pattern 168 may be covered or at least partially covered with an outer insulating spacer 118. The outer insulating spacer 118 may cover or at least partially cover one or both sidewalls of the main gate part 160M on the upper surface of each of the plurality of nanosheet stacks NSS. The outer insulating spacer 118 may be, for example, spaced apart from the gate line 160 with the gate dielectric layer 152 therebetween.

As illustrated in FIG. 2A, an inner insulating spacer 116 may be arranged between each of the plurality of sub-gate parts 160S and one corresponding source/drain region 130. For example, the inner insulating spacer 116 may be arranged between the protrusion P of the source/drain region 130 and each of the plurality of sub-gate parts 160S. For example, the inner insulating spacer 116 may be spaced apart from the sub-gate part 160S in the first horizontal direction (X direction) with the gate dielectric layer 152 therebetween. Hereinafter, the inner insulating spacer 116 will be described in detail.

Referring to FIG. 3, the inner insulating spacer 116 may be arranged between the source/drain region 130 and the sub-gate part 160S in the first horizontal direction (X-direction). For example, the inner insulating spacer 116 may include a first sidewall 116_S1 facing the source/drain region 130 and a second sidewall 116_S2 facing the sub-gate part 160S. The first side wall 116_S1 and the second side wall 116_S2 may be opposite to each other in the first horizontal direction (X direction).

In some example embodiments, the first sidewall 116_S1 may contact (for example, directly contact) the source/drain region 130. For example, the first sidewall 116_S1 may contact (for example, directly contact) the protrusion P of the source/drain region 130. As described above, as the protrusion P protrudes toward the sub-gate part 160S, the first sidewall 116_S1 contacting the protrusion P may be recessed toward the inside of the inner insulating spacer 116 (for example, recessed inwardly). For example, the first side wall 116_S1 may include a part recessed toward the inside of the inner insulating spacer 116.

In some example embodiments, the second sidewall 116_S2 may be in contact (for example, direct contact) with the gate dielectric layer 152. The second sidewall 116_S2 may be recessed toward the inside of the inner insulating spacer 116. For example, the second side wall 116_S2 may include a part recessed toward the inside of the inner insulating spacer 116 (for example, recessed inwardly). For example, a part of the second side wall 116_S2 that is recessed toward the inside of the inner insulating spacer 116 may be a part of the second sub-part 116_2. For example, apart of the second sidewall 116_S2 that is recessed toward the inside of the inner insulating spacer 116 may be a sidewall of the second sub-part 116_2 toward (for example, facing) the sub-gate part 160S. From a cross-sectional perspective, the sidewall facing the sub-gate part 160S of the second sub-part 116_2 may not include a part that is coplanar with the sidewall of the first sub-part 116_1 facing the sub-gate part 160S.

In some example embodiments, the width of the inner insulating spacer 116 in the first horizontal direction (X direction) may not be constant, as the first and second sidewalls 116_S1 and 116_S2 of the inner insulating spacer 116 include parts recessed toward the inside of the inner insulating spacer 116, respectively. For example, the width of the inner insulating spacer 116 in width in the first horizontal direction (X direction) may decrease and then increase in (for example, when moving in) the vertical direction (Z direction). For example, the inner insulating spacer 116 may include a part the width in the first horizontal direction (X direction) of which decreases and then increases in (for example, when moving in) the vertical direction (Z direction).

In some example embodiments, as the second sidewall 116_S2 of the inner insulating spacer 116 facing the sub-gate part 160S is recessed toward the inside of the inner insulating spacer 116, the sub-gate part 160S may have a convex shape toward (for example, with respect to) the inner insulating spacer 116. Accordingly, the width of the sub-gate part 160S in the first horizontal direction (X direction) may not be constant in (for example, when moving in) the vertical direction (Z direction). For example, the width of the sub-gate part 160S in the first horizontal direction (X direction) may increase and then decrease in (for example, when moving in) the vertical direction (Z direction). For example, the sub-gate part 160S may include a part the width in the first horizontal direction (X direction) of which increases and then decreases in (for example, when moving in) the vertical direction (Z direction) (for example, according to vertical level).

In some example embodiments, the inner insulating spacer 116 may include the first sub-part 116_1 and the second sub-part 1162 arranged in the vertical direction (Z direction) (for example, overlap or at least partially overlap with each other in the vertical direction). For example, the inner insulating spacer 116 may include the first sub-part 1161 that contacts (for example, directly contacts) an adjacent nanosheet among the plurality of nanosheets N1, N2, and N3. For example, the inner insulating spacer 116 may include two first sub-parts 116_1 contacting the adjacent second nanosheet N2 and the third nanosheet N3, respectively, among the plurality of nanosheets N1, N2, and N3. The two first sub-parts 116_1 of the inner insulating spacer 116 may overlap or at least partially overlap with each other in the vertical direction (Z direction).

The second sub-part 116_2 of the inner insulating spacer 116 may be arranged between the two first sub-parts 116_1. For example, the second sub-part 116_2 may be arranged between the two first sub-parts 116_1 in the vertical direction (Z direction). The second sub-part 116_2 may overlap or at least partially overlap with the two first sub-parts 116_1 in the vertical direction (Z direction).

In some example embodiments, the second sub-part 1162 may not directly contact adjacent nanosheets among the plurality of nanosheets N1, N2, and N3. For example, the second sub-part 116_2 may not directly contact the adjacent second nanosheet N2 and the adjacent third nanosheet N3 among the plurality of nanosheets N1, N2, and N3. For example, the second sub-part 1162 may be spaced apart from the second nanosheet N2 with the first sub-part 116_1 therebetween. For example, the second sub-part 116_2 may be spaced apart from the third nanosheet N3 with the first sub-part 116_1 therebetween, but example embodiments are not limited thereto.

The first sub-part 116_1 and the second sub-part 116_2 may each include, for example, one or more insulating materials. The first sub-part 116_1 and the second sub-part 1162 may each include different insulating materials. For example, the first sub-part 116_1 may include silicon nitride, and the second sub-part 1162 may include silicon oxide. For example, the first sub-part 116_1 may include polysilicon, and the second sub-part 116_2 may include oxide. However, example embodiments are not limited thereto.

In some example embodiments, referring also to FIG. 4, the first sub-part 1161 may include a first part 116_S11 that is part of the first sidewall 116_S1. The second sub-part 116_2 may include a second part 116_S12 that is part of the first sidewall 116_S1. In other words, two first parts 116_S11 and one second part 116_S12 may be understood as constituting or at least partially constituting the first sidewall 116_S1.

The first part 116_S11 may include a part recessed toward the inside of the first sub-part 116_1. The second part 116_S12 may include a part recessed toward the inside of the second sub-part 116_2.

In some example embodiments, as illustrated in FIG. 4, interfaces 116_12 between the first sub-part 116_1 and the second sub-part 116_2 may not be parallel to interfaces between the inner insulating spacer 116 and the adjacent nanosheets among the plurality of nanosheets N1, N2, and N3, but example embodiments are not limited thereto.

Accordingly, the vertical thickness of the first sub-part 1161 may not be constant. For example, the vertical thickness of the first sub-part 1161 may decrease toward (for example, when horizontally moving towards) the sub-gate part 160S. For example, the first sub-part 116_1 may include a part the vertical thickness of which decreases toward (for example, when moving towards or as the first sub-part 116 is closer to) the sub-gate part 160S.

In some example embodiments, the interfaces 116_12 between each of the first sub-parts 116_1 and the second sub-part 116_2 may contact (for example, directly contact) the source/drain region 130. The vertical levels of the interfaces 116_12 between each of the first sub-parts 116_1 and the second sub-part 1162 may not be constant. For example, the vertical levels of the interfaces 11612 may not be constant in the first horizontal direction (X direction).

In some example embodiments, the first sub-part 1161 may include the first part 116_S11 that may be recessed toward the inside. Accordingly, the width of the first sub-part 116_1 in the first horizontal direction (X direction) may not be constant. For example, the width of the first sub-part 1161 in the first horizontal direction (X direction) may not be constant in the vertical direction (Z direction). For example, the first sub-part 116_1 in the first horizontal direction (X direction) may include a part the width of which decreases in a direction facing (for example, toward or when moving towards) the adjacent second sub-part 116_2. For example, each of the two first sub-parts 1161 may include a part the width in the first horizontal direction (X direction) of which decreases in a direction toward the second sub-part 116_2.

In some example embodiments, referring to FIG. 4, two interfaces 116_12 between the two first sub-parts 116_1 and the second sub-part 1162 may not be parallel to interfaces between the inner insulating spacer 116 and the adjacent nanosheets among the plurality of nanosheets N1, N2, and N3. For example, the distance between the two interfaces 116_12 between the two first sub-parts 116_1 and the second sub-part 1162 may increase toward (for example, when moving toward or as each first subpart is closer to) the sub-gate part 160S. For example, the distance between the interfaces 116_12 may increase toward the sub-gate part 160S.

Accordingly, the vertical thickness of the second sub-part 116_2 may not be constant. For example, the vertical thickness of the second sub-part 116_2 may increase toward the sub-gate part 160S. For example, the second sub-part 1162 may include a part the vertical thickness of which increases toward (for example, when moving towards or as the second subpart is closer to) the sub-gate part 160S.

In some example embodiments, the second sub-part 1162 may include the second part 116_S12 that may be recessed toward the inside. Accordingly, the width of the second sub-part 116_2 in the first horizontal direction (X direction) may not be constant. For example, the width of the second sub-part 116_2 in the first horizontal direction (X direction) may not be constant in the vertical direction (Z direction). For example, the second sub-part 116_2 in the first horizontal direction (X direction) may include a part the width of which increases in a direction facing the adjacent first sub-part 116_1.

In some example embodiments, the first sub-part 116_1 and the second sub-part 116_2 may each contact (for example, directly contact) the source/drain region 130. For example, the first sub-part 116_1 and the second sub-part 116_2 may each contact (for example, directly contact) the source/drain region 130 on the first sidewall 116_S1. For example, the first sub-part 116_1 and the second sub-part 116_2 may each contact (for example, directly contact) the protrusion P of the source/drain region 130 on the first sidewall 116_S1.

For example, as illustrated in FIG. 4, the first sub-part 1161 may contact (for example, directly contact) the source/drain region 130 at the first part 116_S11 of the first sidewall 116_S1. For example, the second sub-part 1162 may contact (for example, directly contact) the source/drain region 130 at the second part 116_S12 of the first sidewall 116_S1.

In some example embodiments, a contact area of one first sub-part 116_1 with the source/drain region 130 may be different from a contact area of the second sub-part 116_2 with the source/drain region 130. For example, a contact area of the first part 116_S11 of the first sidewall 116_S1 of one first sub-part 116_1 with the source/drain region 130 may be different from a contact area of the second part 116_S12 of the first sidewall 116_S1 of the second sub-part 116_2 with the source/drain region 130. For example, a contact area A1 of the first part 116_S11 of the first sidewall 116_S1 of one first sub-part 116_1 with the source/drain region 130 may be smaller than a contact area A2 of the second part 116_S12 of the first sidewall 116_S1 of the second sub-part 116_2 with the source/drain region 130.

In some example embodiments, the first sub-part 116_1 and the second sub-part 116_2 may each contact (for example, directly contact) the gate dielectric layer 152. For example, the first sub-part 116_1 and the second sub-part 116_2 may each contact (for example, directly contact) the gate dielectric layer 152 at the second sidewall 116_S2.

For example, as illustrated in FIG. 4, a contact area of one first sub-part 1161 with the gate dielectric layer 152 may be different from a contact area of the second sub-part 116_2 with the gate dielectric layer 152. For example, a contact area of one first sub-part 116_1 with the gate dielectric layer 152 may be smaller than a contact area of the second sub-part 116_2 with the gate dielectric layer 152.

As illustrated in FIG. 2B, a plurality of recess-side insulating spacers 119 covering sidewalls of the source/drain region 130 may be on the upper surface of the device isolation layer 112. In some example embodiments, each of the plurality of recess-side insulating spacers 119 may be integrally connected to the outer insulating spacer 118 adjacent thereto.

Each of the plurality of outer insulating spacers 118 and the plurality of recess-side insulating spacers 119 may include, for example, silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used herein, refer to materials including elements included in each of the terms, and are not chemical formulae representing a stoichiometric relationship.

A metal silicide layer 172 may be formed on the upper surface of each of the plurality of source/drain regions 130. The metal silicide layer 172 may include for example, one or more metals including, for example, Ti, W, Ru, Nb, Mo, Hf, Ni, Co, Pt, Yb, Tb, Dy, Er, and/or Pd. For example, the metal silicide layer 172 may include titanium silicide, but is not limited thereto.

The plurality of source/drain regions 130, the plurality of metal silicide layers 172, and a plurality of outer insulating spacers 128 may be covered or at least partially covered with an insulating liner 142 on the substrate 102. In some example embodiments, the insulating liner 142 may be omitted. An inter-gate insulating layer 144 may be on the insulating liner 142. When the insulating liner 142 is omitted, the inter-gate insulating layer 144 may be in contact (for example, direct contact) with the plurality of source/drain regions 130.

The insulating liner 142 and the inter-gate insulating layer 144 may be sequentially on the plurality of source/drain regions 130 and the plurality of metal silicide layers 172. The insulating liner 142 and the inter-gate insulating layer 144 may constitute or at least partially constitute an insulating structure. In some example embodiments, the insulating liner 142 may include, for example, silicon nitride, SiCN, SiBN, SiON, SiOCN, SiBCN, or a combination thereof, but is not limited thereto. The inter-gate insulating layer 144 may include, for example, a silicon oxide layer, but is not limited thereto.

Both sidewalls of each of the plurality of sub-gate parts 160S included in the plurality of gate lines 160 may be spaced apart from the source/drain region 130 with the gate dielectric layer 152 therebetween. The gate dielectric layer 152 may be arranged between the sub-gate part 160S included in the gate line 160 and each of the first nanosheet N1, the second nanosheet N2, and the third nanosheet N3, and the gate dielectric layer 152 may be arranged between the sub-gate part 160S included in the gate line 160 and the source/drain region 130.

The plurality of nanosheet stacks NSS may be on the fin upper surface FT of each of the plurality of fin-type active regions FA in regions where the plurality of fin-type active regions FA and the plurality of gate lines 160 intersect (for example, overlap or at least partially overlap with each other), and may face the fin upper surface FT of each of the fin-type active regions FA at a position spaced apart from each of the fin-type active regions FA. A plurality of nanosheet transistors may be formed in parts on the substrate 102 where the plurality of fin-type active regions FA and the plurality of gate lines 160 intersect.

As illustrated in FIGS. 2A and 2B, an active contact CA may be on the source/drain region 130. The active contact CA may penetrate (for example, extend or at least partially extend through) the inter-gate insulating layer 144 and the insulating liner 142 in the vertical direction (Z direction) to be in contact (for example, direct contact) with the metal silicide layer 172. The active contact CA may be configured to be electrically connected to the source/drain regions 130 through the metal silicide layer 172.

The active contact CA may include a conductive barrier pattern 174 and a contact plug 176 sequentially stacked on the source/drain region 130. The conductive barrier pattern 174 may surround or at least partially surround the bottom surface and the sidewall of the contact plug 176 and may be in contact (for example, direct contact) with the bottom surface and the sidewall of the contact plug 176. The active contact CA may penetrate (for example, extend or at least partially extend through) the inter-gate insulating layer 144 and the insulating liner 142 and may extend lengthwise in the vertical direction (Z direction). The conductive barrier pattern 174 may be arranged between the metal silicide layer 172 and the contact plug 176. The conductive barrier pattern 174 may have a surface in contact (for example, direct contact) with the metal silicide layer 172 and a surface in contact (for example, direct contact) with the contact plug 176. In some example embodiments, the conductive barrier pattern 174 may include metal or metal nitride. For example, the conductive barrier pattern 174 may include Ti, Ta, W, TiN, TaN, WN, WCN, TiSiN, TaSiN, WSiN, or a combination thereof, but is not limited thereto. The contact plug 176 may, for example, include molybdenum (Mo), copper (Cu), tungsten (W), cobalt (Co), ruthenium (Ru), manganese (Mn), titanium (Ti), tantalum (Ta), aluminum (Al), or any alloy and/or combination thereof, but is not limited thereto.

As illustrated in FIGS. 2A to 2C, the upper surface of each of the active contact CA, the capping insulating pattern 168, and the inter-gate insulating layer 144 may be covered or at least partially covered with the upper insulating structure 180. The upper insulating structure 180 may include an etching stop layer 182 and an interlayer insulating layer 184 sequentially stacked on each of the active contact CA, the plurality of capping insulating patterns 168, and the inter-gate insulating layer 144. The etching stop layer 182 may include, for example, a silicon carbide (SiC), a silicon nitride (SiN), a nitrogen-doped silicon carbide (SiC:N), SiOC, AlN, AlON, AlO, AlOC, or a combination thereof, but example embodiments are not limited thereto. The interlayer insulating layer 184 may include, for example, an oxide layer, a nitride layer, an ultra low-k (ULK) layer having an ultra low dielectric constant K of about 2.2 to about 2.4, or a combination thereof. For example, the interlayer insulating layer 184 may include a tetraethylorthosilicate (TEOS) layer, a high density plasma (HDP) oxide layer, a boro-phospho-silicate glass (BPSG) layer, a flowable chemical vapor deposition (FCVD) oxide layer, a SiON layer, a SiN layer, a SiOC layer, a SiCOH layer, or a combination thereof, but is not limited thereto.

As illustrated in FIGS. 2A and 2B, a via contact VA may be on the active contact CA. The via contact VA may penetrate (for extend or at least partially extend through) the upper insulating structure 180 and be in contact (for example, direct contact) with the active contact CA. Each of the plurality of source/drain regions 130 may be configured to be electrically connected to the via contact VA through the metal silicide layer 172 and the active contact CA. The bottom surface of the via contact VA may be in contact (for example, direct contact) with the upper surface of the active contact CA. The via contact VA may include, for example, tungsten (W), molybdenum (Mo), and/or ruthenium (Ru), but is not limited thereto.

A wiring line M1 may be arranged to penetrate (for example, extend or at least partially extend through) an upper insulating layer 192. The wiring line M1 may be connected to the via contact VA at the bottom of the wiring line M1. In some example embodiments, the wiring line M1 may extend in the first horizontal direction X. The wiring line M1 may include, for example, molybdenum (Mo), copper (Cu), tungsten (W), cobalt (Co), ruthenium (Ru), manganese (Mn), titanium (Ti), tantalum (Ta), aluminum (Al), a combination thereof, and/or an alloy thereof, but is not limited thereto.

The integrated circuit device 100 according to some example embodiments may include the inner insulating spacer 116 including the first sub-part 116_1 and the second sub-part 116_2. For example, the inner insulating spacer 116 of the integrated circuit device 100 includes different materials, to improve performance and/or reliability. For example, the inner insulating spacer 116 of the integrated circuit device 100 includes different materials in respective sub-parts that contact (for example, directly contact) the channel region and the source/drain region 130, to accordingly improve performance and reliability.

For example, the first sub-part 116_1 in contact (for example, direct contact) with the channel region may include, for example, silicon nitride, which may improve channel resistance and cause and/or contribute to a mobility boosting effect.

For example, the second sub-part 116_2 in contact (for example, direct contact) with the source/drain region 130 may include, for example, silicon oxide to reduce gate-to-source/drain region capacitance.

For example, as described with reference to FIG. 4, a contact area A1 of at least one first sub-part 116_1 with the source/drain region 130 may be smaller than a contact area A2 of the second sub-part 116_2 with the source/drain region 130. When the first sub-part 116_1 includes, for example, silicon nitride, the second sub-part 116_2 may include, for example, silicon oxide having a lower dielectric constant (low-k). Accordingly, the integrated circuit device 100 including the inner insulating spacer 116 according to inventive concepts may have an effect of reducing a gate-to-source/drain region capacitance.

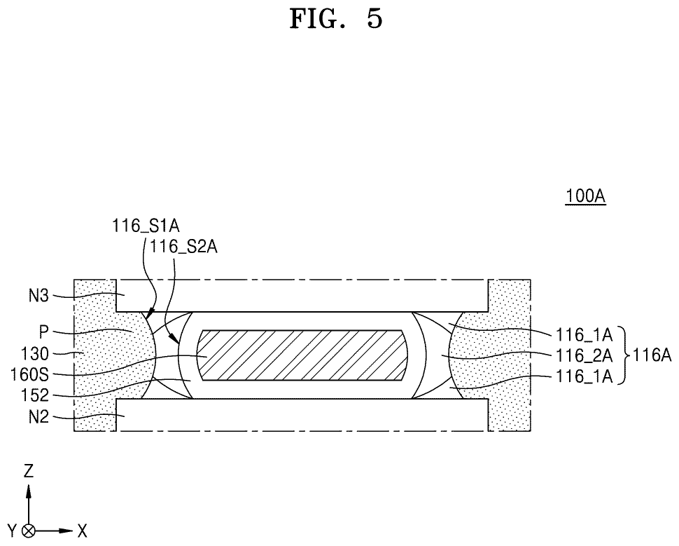

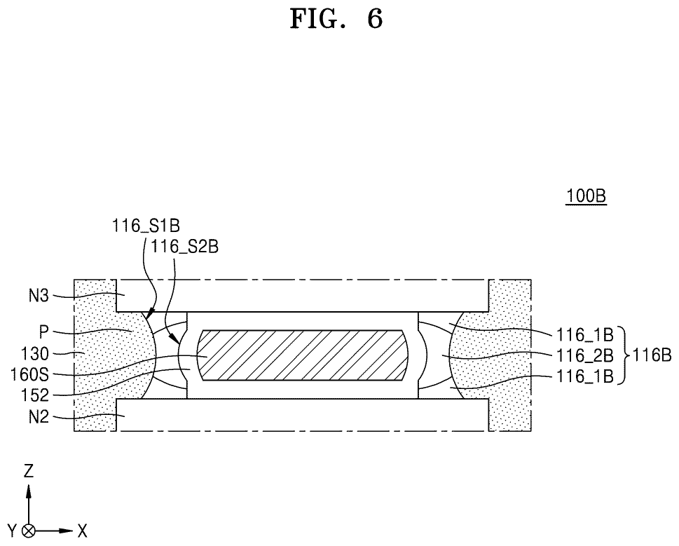

FIGS. 5 and 6 are enlarged cross-sectional views for explaining integrated circuit devices 100A and 100B according to some example embodiments. For example, FIGS. 5 and 6 are enlarged cross-sectional views of regions corresponding to the region EX1 of FIG. 2A. Hereinafter, a difference from the integrated circuit device 100 described with reference to FIGS. 1, 2A to 2C, FIGS. 3 and 4 will be mainly described. Descriptions of common components will be omitted.

Referring to FIG. 5, the integrated circuit device 100A may include an inner insulating spacer 116A arranged between the sub-gate part 160S and the source/drain region 130. The inner insulating spacer 116A may be arranged between the source/drain region 130 and the sub-gate part 160S in the first horizontal direction (X-direction). For example, the inner insulating spacer 116A may include a first sidewall 116_S1A facing the source/drain region 130 and a second sidewall 116_S2A facing the sub-gate part 160S. The first side wall 116_S1A and the second side wall 116_S2A may be opposite to each other in the first horizontal direction (X direction).

In some example embodiments, the first sidewall 116_S1A may contact (for example, directly contact) the source/drain region 130. For example, the first sidewall 116_S1A may contact (for example, directly contact) the protrusion P of the source/drain region 130. The first side wall 116_S1A may include a part recessed toward the inside of the inner insulating spacer 116.

In some example embodiments, the second sidewall 116_S2A may be in contact (for example, direct contact) with the gate dielectric layer 152. The second sidewall 116_S2A may be recessed toward the inside of the inner insulating spacer 116. For example, the second side wall 116_S2A may include a part recessed toward the inside of the inner insulating spacer 116.

Accordingly, the width of the inner insulating spacer 116A in the first horizontal direction (X direction) may decrease and then increase in the vertical direction (Z direction) (for example when moving upwards or downwards in the vertical (Z) direction from one end of the insulating inner spacer to another end).

In some example embodiments, the inner insulating spacer 116A may include the first sub-part 116_1A and the second sub-part 116_2A arranged in the vertical direction (Z direction). For example, the inner insulating spacer 116A may include two first sub-parts 116_1A contacting the adjacent second nanosheet N2 and the adjacent third nanosheet N3, respectively, among the plurality of nanosheets N1, N2, and N3. The second sub-part 116_2A of the inner insulating spacer 116A may be arranged between the two first sub-parts 116_1. For example, the second sub-part 116_2A may be arranged between the two first sub-parts 116_1A in the vertical direction (Z direction).

In some example embodiments, the first sub-part 116_1A and the second sub-part 116_2A may each contact (for example, directly contact) the source/drain region 130. For example, the first sub-part 116_1A and the second sub-part 116_2A may each contact (for example, directly contact) the source/drain region 130 on the first sidewall 116_S1A. For example, the first sub-part 116_1A and the second sub-part 116_2A may each contact (for example, directly contact) the protrusion P of the source/drain region 130 on the first sidewall 116_S1A.

In some example embodiments, the sub-part 116_2A may be in contact (for example, direct contact) with the gate dielectric layer 152. For example, the second sub-part 116_2A may be in contact (for example, direct contact) with the gate dielectric layer 152 at the second sidewall 116_S2A. Meanwhile, the first sub-part 116_1A may not be in contact (for example, direct contact) with the gate dielectric layer 152. For example, the first sub-part 116_1A may not be in contact with the gate dielectric layer 152 at the second sidewall 116_S2A.

Referring to FIG. 6, the integrated circuit device 100B may include an inner insulating spacer 116B arranged between the sub-gate part 160S and the source/drain region 130. The inner insulating spacer 116B may be arranged between the source/drain region 130 and the sub-gate part 160S in the first horizontal direction (X-direction). For example, the inner insulating spacer 116B may include a first sidewall 116_S1B facing the source/drain region 130 and a second sidewall 116_S2B facing the sub-gate part 160S. The first side wall 116_S1B and the second side wall 116_S2B may be opposite to each other in the first horizontal direction (X direction).

In some example embodiments, the first sidewall 116_S1B may contact (for example, directly contact) the source/drain region 130. For example, the first sidewall 116_S1B may contact (for example, directly contact) the protrusion P of the source/drain region 130. The first side wall 116_S1B may include a part recessed toward the inside of the inner insulating spacer 116.

In some example embodiments, the second sidewall 116_S2B may be in contact (for example, direct contact) with the gate dielectric layer 152. The second sidewall 116_S2B may be recessed toward the inside of the inner insulating spacer 116 (for example, inwardly recessed). For example, the second side wall 116_S2B may include a part recessed toward the inside of the inner insulating spacer 116. For example, a part of the second sidewall 116_S2B that is recessed toward the inside of the inner insulating spacer 116B may be part of a sidewall toward the sub-gate part 160SB of the second sub-part 116_2B. From a cross-sectional perspective, the sidewall facing the sub-gate part 160SB of the second sub-part 116_2B may not include a part that is coplanar with the sidewall facing the sub-gate part 160SB of the first sub-part 116_1B.

Accordingly, the width of the inner insulating spacer 116B in the first horizontal direction (X direction) may decrease and then increase in the vertical direction (Z direction).

In some example embodiments, the inner insulating spacer 116B may include the first sub-part 116_1B and the second sub-part 116_2B arranged in the vertical direction (Z direction). For example, the inner insulating spacer 116B may include two first sub-parts 116_1B contacting (for example, directly contacting) the adjacent second nanosheet N2 and the adjacent third nanosheet N3, respectively, among the plurality of nanosheets N1, N2, and N3. The second sub-part 116_2B of the inner insulating spacer 116B may be arranged between the two first sub-parts 116_1. For example, the second sub-part 116_2B may be arranged between the two first sub-parts 116_1B in the vertical direction (Z direction).

In some example embodiments, the first sub-part 116_1B and the second sub-part 116_2B may each contact (for example, directly contact) the source/drain region 130. For example, the first sub-part 116_1B and the second sub-part 116_2B may each contact (for example, directly contact) the source/drain region 130 on the first sidewall 116_S1B. For example, the first sub-part 116_1B and the second sub-part 116_2B may each contact (for example, directly contact) the protrusion P of the source/drain region 130 on the first sidewall 116_S1B.

In some example embodiments, the first sub-part 116_1B and the second sub-part 116_2B may each contact (for example, directly contact) the gate dielectric layer 152. For example, the first sub-part 116_1B and the second sub-part 116_2B may each contact (for example, directly contact) the gate dielectric layer 152 at the second sidewall 116_S2B.

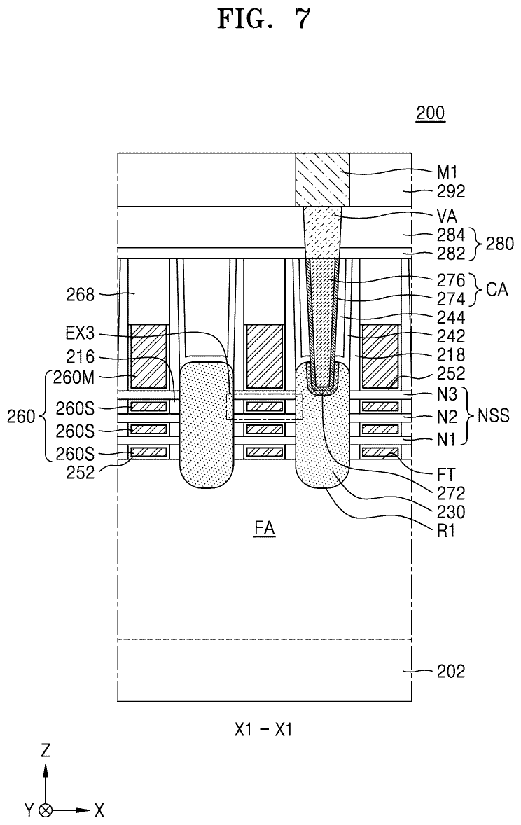

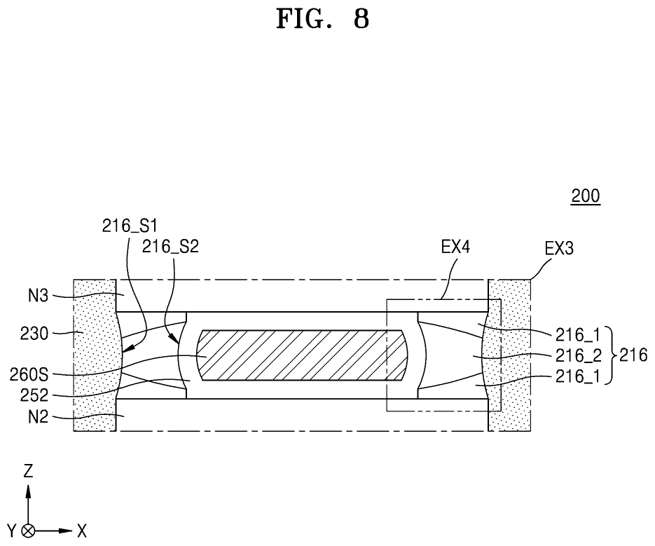

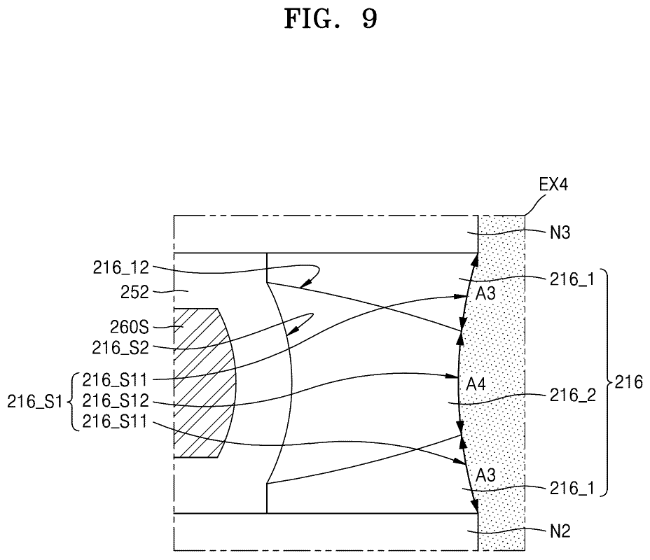

FIG. 7 is a cross-sectional view for explaining an integrated circuit device 200 according to some example embodiments. FIG. 8 is an enlarged cross-sectional view for explaining an integrated circuit device 200 according to some example embodiments. FIG. 9 is an enlarged cross-sectional view for explaining an integrated circuit device 200 according to some example embodiments. Specifically, FIG. 8 is an enlarged cross-sectional view of the region EX3 of FIG. 7, and FIG. 9 is an enlarged cross-sectional view of the region EX4 of FIG. 8. Hereinafter, a difference from the integrated circuit device 100 described with reference to FIGS. 1, 2A to 2C, FIGS. 3 and 4 will be mainly described.

Referring to FIGS. 7 to 9, an integrated circuit device 200 may include a substrate 202 and a plurality of fin-type active regions FA protruding from the substrate 202.

A plurality of gate lines 260 may be on each of the plurality of fin-type active regions FA. Each of the plurality of gate lines 260 may extend long in the second horizontal direction (Y direction). In regions where the plurality of fin-type active regions FA and the plurality of gate lines 260 cross each other, a plurality of nanosheet stacks NSS may be on a fin upper surface FT of each of the plurality of fin-type active regions FA. A gate dielectric layer 152 may be arranged between the nanosheet stack NSS and the gate line 260. The descriptions of the plurality of gate lines 260 and the gate dielectric layers 252 may refer to the descriptions of the plurality of gate lines 160 (see FIGS. 1, 2A and 2C) and the gate dielectric layers 152 (see FIGS. 1, 2A and 2C), respectively. Descriptions of the plurality of nanosheet stacks NSS are similar to those described with reference to FIGS. 1, 2A to 2C, 3 and 4.

A plurality of source/drain regions 230 may be on the fin-type active region FA. The plurality of source/drain regions 230 may be arranged at positions adjacent to at least one gate line 260, and may be in contact (for example, direct contact) with the first nanosheet N1, the second nanosheet N2, and the third nanosheet N3 included in the adjacent nanosheet stack NSS, respectively. The source/drain region 230 may or may not include a protrusion protruding toward the sub-gate part 260S.

A description of the capping insulating pattern 268, the outer insulating spacer 218, the metal silicide layer 272, the insulating liner 242, the inter-gate insulating layer 244, the conductive barrier pattern 274 and the contact plug 276 included in the active contact CA, the upper insulating structure 280, the etching stop layer 282 and the interlayer insulating layer 284 included in the upper insulating structure 280, the via contact line VA, the wiring line M1, and the upper insulating layer 292 of the integrated circuit device 200 may be given to FIGS. 1 and 2A to 2C.

The inner insulating spacer 216 may be arranged between each of the plurality of sub-gate parts 260S and the source/drain region 230. The inner insulating spacer 216 may be generally similar to the inner insulating spacer 116 described with reference to FIGS. 3 and 4.

Referring to FIG. 8, the inner insulating spacer 216 may be arranged between the source/drain region 230 and the sub-gate part 160S in the first horizontal direction (X-direction). For example, the inner insulating spacer 216 may include a first sidewall 216_S1 facing the source/drain region 230 and a second sidewall 216_S2 facing the sub-gate part 160S. The first side wall 216_S1 and the second side wall 216_S2 may be opposite to each other in the first horizontal direction (X direction).

In some example embodiments, the first sidewall 216_S1 may contact (for example, directly contact) the source/drain region 230. The first sidewall 216_S2 may be recessed toward the inside of the inner insulating spacer 216. For example, the first side wall 216_S1 may include a part recessed toward the inside of the inner insulating spacer 216.

In some example embodiments, the second sidewall 216_S2 may be in contact (for example, direct contact) with the gate dielectric layer 152. The second sidewall 216_S2 may be recessed toward the inside of the inner insulating spacer 216. For example, the second side wall 216_S2 may include a part recessed toward the inside of the inner insulating spacer 216.

For example, the inner insulating spacer 216 may include a part the width (e.g. in the first horizontal direction (X direction)) of which decreases and then increases in (for example, when moving in) the vertical direction (Z direction).

For example, the sub-gate part 260S may include apart the width (e.g. width in the first horizontal direction (X direction)) of which increases and then decreases in the vertical direction (Z direction).

In some example embodiments, the inner insulating spacer 216 may include the two first sub-parts 216_1 and the second sub-part 216_2 arranged in the vertical direction (Z direction). For example, the inner insulating spacer 216 may include two first sub-parts 216_1 contacting the adjacent second nanosheet N2 and the third nanosheet N3, respectively, among the plurality of nanosheets N1, N2, and N3. The second sub-part 216_2 of the inner insulating spacer 216 may be arranged between the two first sub-parts 216_1 in the vertical direction (Z direction).

In some example embodiments, the second sub-part 2162 may not directly contact adjacent nanosheets among the plurality of nanosheets N1, N2, and N3. For example, the second sub-part 216_2 may not directly contact the adjacent second nanosheet N2 and the adjacent third nanosheet N3 among the plurality of nanosheets N1, N2, and N3. For example, the second sub-part 2162 may be spaced apart from the second nanosheet N2 with the first sub-part 216_1 therebetween. For example, the second sub-part 216_2 may be spaced apart from the third nanosheet N3 with the first sub-part 216_1 therebetween.

The first sub-part 216_1 and the second sub-part 216_2 may each include an insulating material. The first sub-part 216_1 and the second sub-part 2162 may each include different insulating materials. For example, the first sub-part 2161 may include silicon nitride, and the second sub-part 216_2 may include silicon oxide. For example, the first sub-part 2161 may include polysilicon, and the second sub-part 2162 may include oxide, but example embodiments are not limited thereto.

In some example embodiments, referring to FIG. 9, interfaces 216_12 between the first sub-part 216_1 and the second sub-part 2162 may not be parallel to interfaces between the inner insulating spacer 216 and the adjacent nanosheets among the plurality of nanosheets N1, N2, and N3. For example, the first sub-part 2161 may include a part the vertical thickness of which decreases toward (for example, when moving toward) the sub-gate part 160S.

For example, the first sub-part 216_1 in the first horizontal direction (X direction) may include a part the width of which decreases in a direction facing the adjacent second sub-part 216_2.

In some example embodiments, referring continuously to FIG. 9, the distance between the respective interfaces 216_12 between the two first sub-parts 216_1 and the second sub-part 216_2 may increase toward the sub-gate part 160S. Among the plurality of interfaces 216_12, the distance between a selected one interface and its corresponding interface may increase as it gets closer (for example, towards or when moving towards) to the sub-gate part 160S. For example, the second sub-part 2162 may include a part the vertical thickness of which increases toward the sub-gate part 160S.

For example, the second sub-part 216_2 in the first horizontal direction (X direction) may include a part the width of which increases in a direction facing the adjacent first sub-part 216_1.

In some example embodiments, the first sub-part 216_1 and the second sub-part 216_2 may each contact (for example, directly contact) the source/drain region 230. For example, the first sub-part 216_1 and the second sub-part 216_2 may each contact (for example, directly contact) the source/drain region 230 on the first sidewall 216_S1.

For example, as illustrated in FIG. 9, the first sub-part 2161 may contact (for example, directly contact) the source/drain region 230 at the first part 216_S11 of the first sidewall 216_S1. For example, the second sub-part 2162 may contact (for example, directly contact) the source/drain region 230 at the second part 216_S12 of the first sidewall 216_S1.

In some example embodiments, a contact area of one first sub-part 216_1 with the source/drain region 230 may be different from a contact area of the second sub-part 216_2 with the source/drain region 230. For example, a contact area of the first part 216_S11 of the first sidewall 216_S1 of one first sub-part 216_1 with the source/drain region 230 may be different from a contact area of the second part 216_S12 of the first sidewall 216_S1 of the second sub-part 216_2 with the source/drain region 230. For example, a contact area A3 of the first part 216_S11 of the first sidewall 216_S1 of one first sub-part 216_1 with the source/drain region 230 may be smaller than a contact area A4 of the second part 216_S12 of the first sidewall 216_S1 of the second sub-part 216_2 with the source/drain region 230.

In some example embodiments, the first sub-part 216_1 and the second sub-part 216_2 may each contact (for example, directly contact) the gate dielectric layer 252. For example, the first sub-part 126_1 and the second sub-part 216_2 may each contact (for example, directly contact) the gate dielectric layer 252 at the second sidewall 216_S2.

For example, as illustrated in FIG. 9, a contact area of one first sub-part 2161 with the gate dielectric layer 252 may be different from a contact area of the second sub-part 216_2 with the gate dielectric layer 252. For example, a contact area of one first sub-part 216_1 with the gate dielectric layer 252 may be smaller than a contact area of the second sub-part 216_2 with the gate dielectric layer 252.

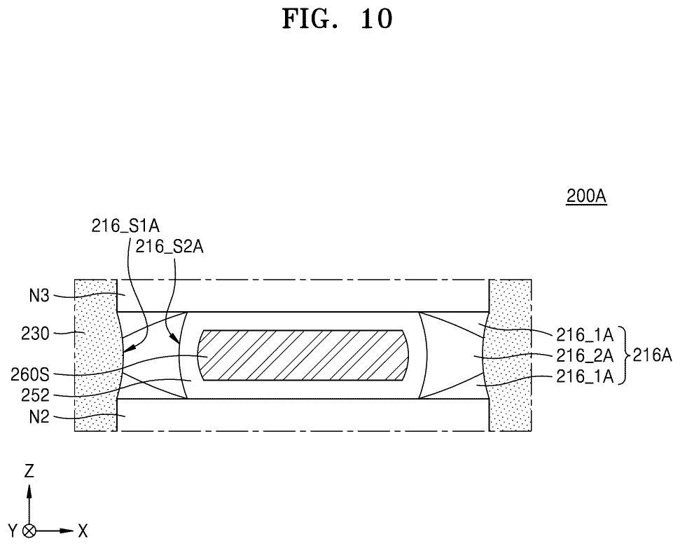

FIG. 10 is an enlarged cross-sectional view for explaining an integrated circuit device 200A according to some example embodiments. FIG. 10 is an enlarged cross-sectional view of a region corresponding to a region EX3 of FIG. 7. Hereinafter, a difference from the integrated circuit device 200 described with reference to FIGS. 7 to 9 will be mainly described, and a description of common components will be omitted.

Referring to FIG. 10, the integrated circuit device 200A may include an inner insulating spacer 216A arranged between the sub-gate part 260S and the source/drain region 230. The inner insulating spacer 216A may be arranged between the source/drain region 230 and the sub-gate part 260S in the first horizontal direction (X-direction). For example, the inner insulating spacer 216A may include a first sidewall 216_S1A facing the source/drain region 230 and a second sidewall 216_S2A facing the sub-gate part 260S. The first side wall 216_S1A and the second side wall 216_S2A may be opposite to each other in the first horizontal direction (X direction).

In some example embodiments, the first sidewall 216_S1A may contact (for example, directly contact) the source/drain region 230. The first side wall 216_S1A may include a part recessed toward the inside of the inner insulating spacer 216.

In some example embodiments, the second sidewall 216_S2A may be in contact (for example, direct contact) with the gate dielectric layer 252. The second sidewall 216_S2A may be recessed toward the inside of the inner insulating spacer 216. For example, the second side wall 216_S2A may include a part recessed toward the inside of the inner insulating spacer 216.

Accordingly, the width of the inner insulating spacer 216A in the first horizontal direction (X direction) may decrease and then increase in the vertical direction (Z direction).

In some example embodiments, the inner insulating spacer 216A may include the first sub-part 216_1A and the second sub-part 216_2A arranged in the vertical direction (Z direction). For example, the inner insulating spacer 216A may include two first sub-parts 216_1A contacting (for example, directly contacting) the adjacent second nanosheet N2 and the third nanosheet N3, respectively, among the plurality of nanosheets N1, N2, and N3. The second sub-part 216_2A of the inner insulating spacer 216A may be arranged between the two first sub-parts 216_1. For example, the second sub-part 216_2A may be arranged between the two first sub-parts 216_1A in the vertical direction (Z direction).

In some example embodiments, the first sub-part 216_1A and the second sub-part 216_2A may each contact (for example, directly contact) the source/drain region 230. For example, the first sub-part 216_1A and the second sub-part 216_2A may each contact (for example, directly contact) the source/drain region 230 on the first sidewall 216_S1A.

In some example embodiments, the second sub-part 216_2A may be in contact (for example, direct contact) with the gate dielectric layer 252. For example, the second sub-part 216_2A may be in contact (for example, direct contact) with the gate dielectric layer 252 at the second sidewall 216_S2A. Meanwhile, the first sub-parts 216_1A may not be in contact (for example, direct contact) with the gate dielectric layer 252. For example, the first sub-part 216_1A may not be in contact (for example, direct contact) with the gate dielectric layer 252 at the second sidewall 216_S2A.

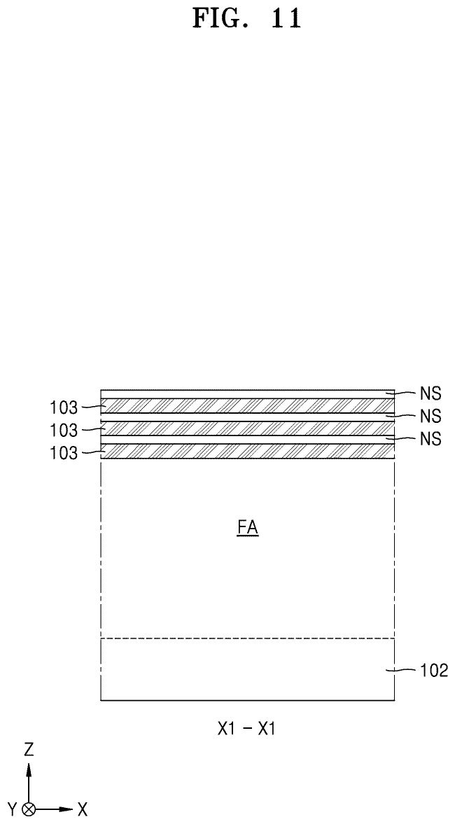

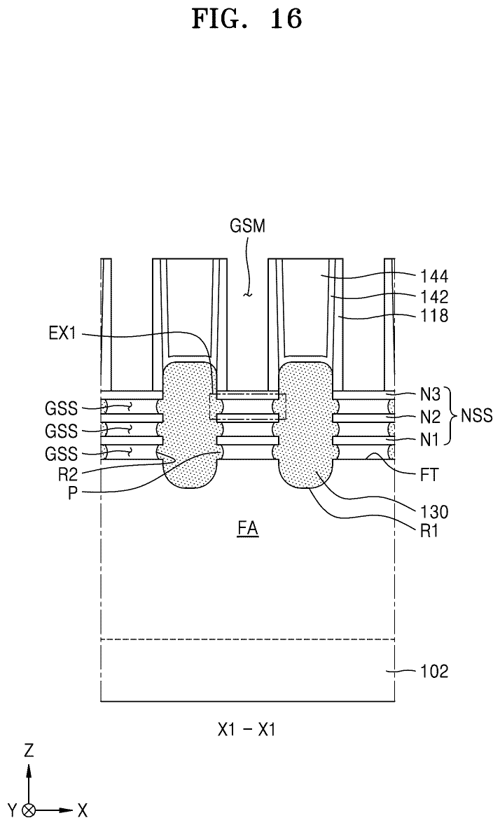

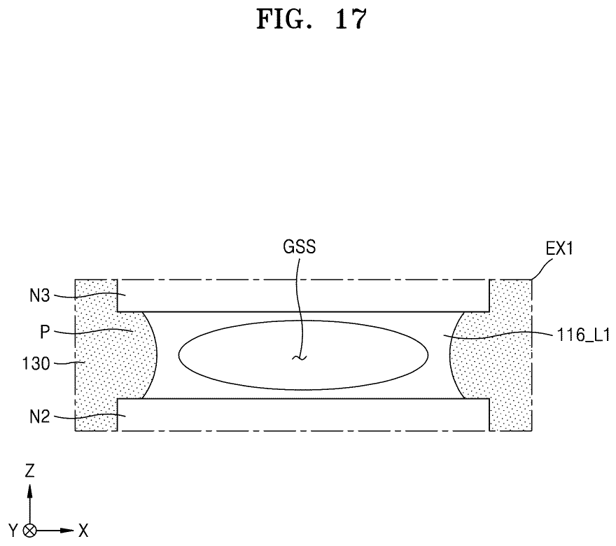

FIGS. 11 to 23 are cross-sectional views illustrating a process order to explain methods of manufacturing an integrated circuit device 100 in accordance with at least some example embodiments of inventive concepts. For example, FIGS. 11 to 16, 22, and 23 are cross-sectional views corresponding to the cross-section along line X1-X1 in FIG. 1, and FIGS. 17 to 21 are enlarged cross-sectional views of the region corresponding to the region EX1 in FIG. 16.

Referring to FIG. 11, a plurality of sacrificial semiconductor layers 103 and a plurality of nanosheet semiconductor layers NS may be alternately stacked one-by-one on a substrate 102. The plurality of sacrificial semiconductor layers 103 and the plurality of nanosheet semiconductor layers NS may include, for example, semiconductor materials having different etch selectivity.

Thereafter, a plurality of fin-type active regions FA extending in the first horizontal direction (X direction) may be formed on the substrate 102 by etching the sacrificial semiconductor layer 103, a plurality of nanosheet semiconductor layers NS, and a part of the substrate 102. A stack structure of the plurality of sacrificial semiconductor layers 103 and the plurality of nanosheet semiconductor layers NS may remain on the fin upper surface FT of each of the plurality of fin-type active regions FA.

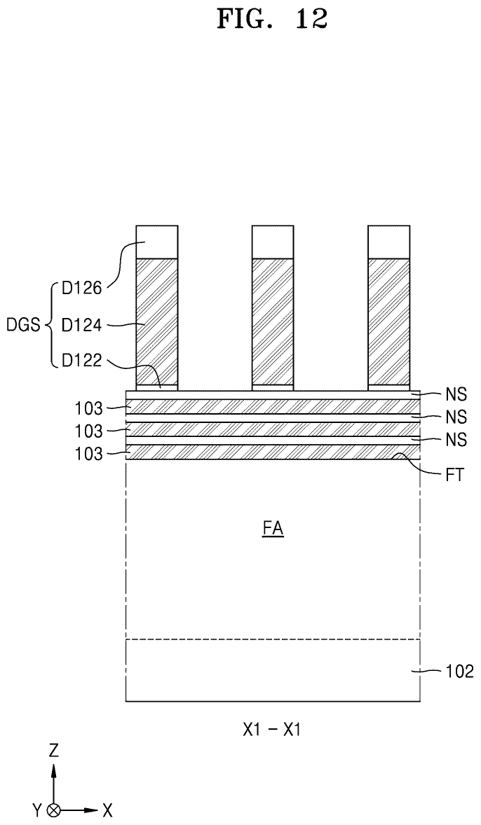

Referring to FIG. 12, a plurality of dummy gate structures DGS may be formed on the stack structure of the plurality of sacrificial semiconductor layers 103 and the plurality of nanosheet semiconductor layers NS.

Each of the plurality of dummy gate structures DGS may be formed to extend lengthwise in the second horizontal direction (Y direction). Each of the plurality of dummy gate structures DGS may have a structure in which an oxide layer D122, a dummy gate layer D124, and a capping layer D126 are sequentially stacked. In some example embodiments, the dummy gate layer D124 may include polysilicon, and the capping layer D126 may include a silicon nitride layer, but example embodiments are not limited thereto.

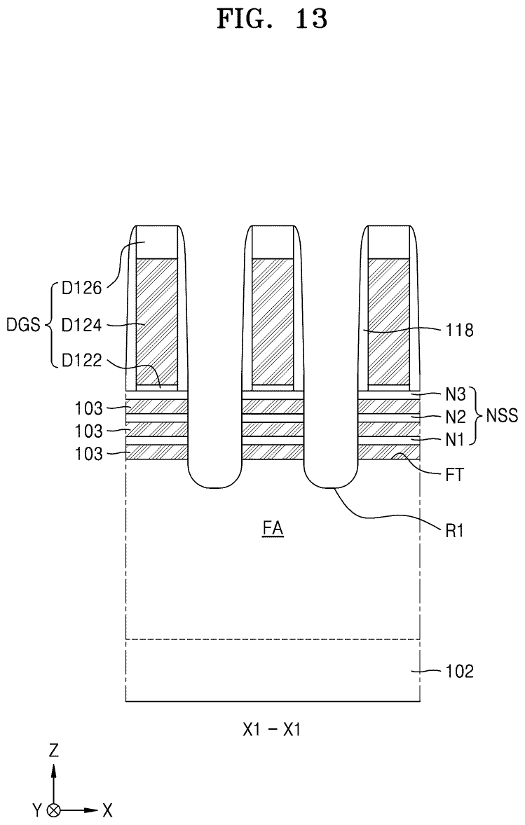

Referring to FIG. 13, after forming a plurality of outer insulating spacers 118 covering both sidewalls of each of the plurality of dummy gate structures DGS, the plurality of dummy gate structures DGS and the plurality of outer insulating spacers 118 are used as etching masks, to etch part of the plurality of sacrificial semiconductor layers 103 and part of the plurality of nanosheet semiconductor layers NS. Accordingly, the plurality of nanosheet semiconductor layers NS are divided into a plurality of nanosheet stacks NSS each including the first nanosheet N1, the second nanosheet N2, and the third nanosheet N3.

A plurality of first recesses R1 may be formed (for example, defined) by the etching process. In formation of the plurality of first recesses R1, etching may be performed using, for example, dry etching, wet etching, or a combination thereof.

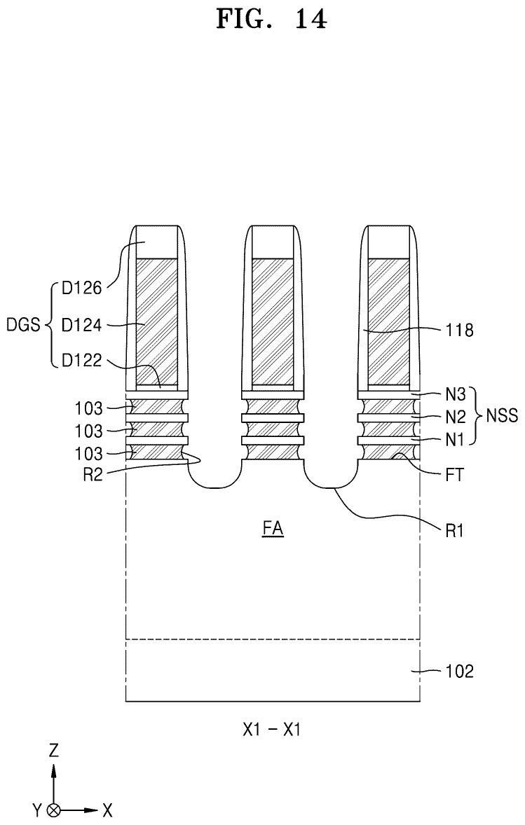

Referring to FIG. 14, the plurality of sacrificial semiconductor layers 103 exposed by the sidewalls of the plurality of first recesses R1 may be etched to form a plurality of second recesses R2. In formation of the plurality of second recesses R2, etching may be performed using, for example, dry etching, wet etching, or a combination thereof. Due to the formation of the second recesses R2, each of the plurality of sacrificial semiconductor layers 103 may have a shape recessed to the inside of each of the plurality of sacrificial semiconductor layers 103.

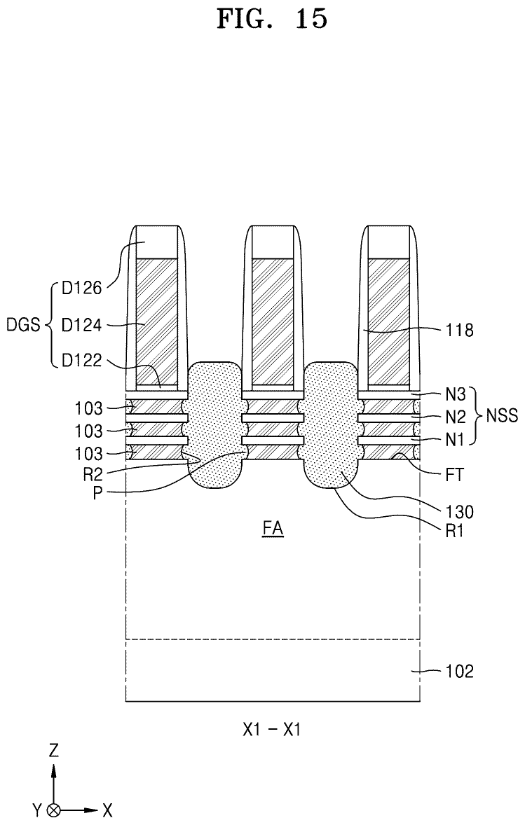

Referring to FIG. 15, a plurality of source/drain regions 130 may be formed inside the plurality of first recesses R1, respectively. In some example embodiments, in formation of a plurality of source/drain regions 130, a semiconductor material may be epitaxially grown from the surface of the fin-type active region FA exposed from the bottom surface of the recess, each sidewall of the first nanosheet N1, the second nanosheet N2, and the third nanosheet N3 included in the nanosheet stack NSS, and each sidewall of the plurality of sacrificial semiconductor layers 103. For example, the protrusion P may be formed together in the second recess R2.

Referring to FIG. 16, an insulating liner 142 is formed to cover or at least partially cover the result of FIG. 15 in which the plurality of source/drain regions 130 are formed, an inter-gate insulating layer 144 is formed on the insulating liner 142, and then the upper surface of the capping layer D126 may be exposed or at least partially exposed by planarizing the insulating liner 142 and the inter-gate insulating layer 144.

Then, the upper surface of the dummy gate layer D124 may be exposed by removing the plurality of capping layers D126, and the insulating liner 142 and the inter-gate insulating layer 144 may be partially removed so that the upper surface of the inter-gate insulating layer 144 and the upper surface of the dummy gate layer D124 have the same, approximately the same, or substantially the same level.

Subsequently, the plurality of sacrificial semiconductor layers 103 remaining on the fin-type active regions FA may be removed through a main gate space GSM to provide a sub-gate space GSS between the first nanosheet N1 and the second nanosheet N2, between the second nanosheet N2 and the third nanosheet N3, and between the first nanosheet N1 and the fin upper surface.

Referring to FIG. 17, a first sub-layer 116_L1 may be formed in the sub-gate space GSS. For example, the first sub-layer 116_L1 may be formed on an adjacent nanosheet among the source/drain region 130 and the plurality of nanosheets N1, N2, and N3 in the sub-gate space GSS. For example, the first sub-layer 116_L1 contacting the protrusion P of the source/drain region 130, the second nanosheet N2, and the third nanosheet N3 may be formed. For example, the first sub-layer 116_L1 may include silicon nitride.

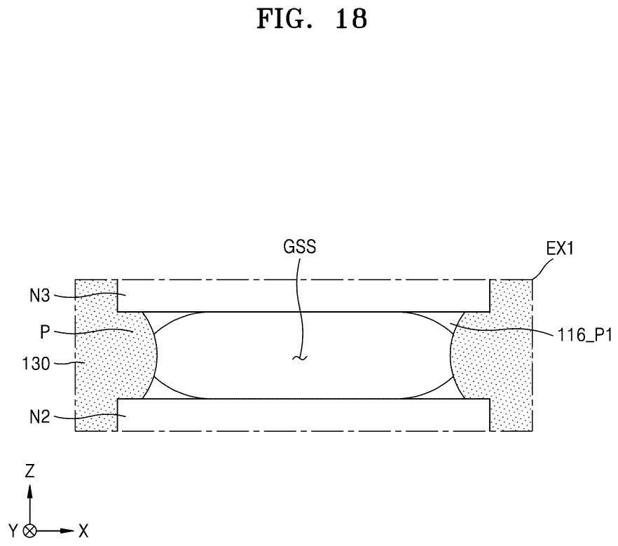

Referring to FIG. 18, a part of the first sub-layer 116_L1 may be removed through the sub-gate space GSS to form a first pre-sub-part 116_P1. For example, a part of the first sub-layer 116_L1 may be removed so that a part of each of the source/drain region 130 and the adjacent nanosheets from among the plurality of nanosheets N1, N2, and N3 is exposed. For example, a part of the first sub-layer 116_L1 may be removed so that a part of each of the protrusion P of the source/drain region 130, the second nanosheet N2, and the third nanosheet N3 is exposed. Accordingly, the first pre-sub-part 116_P1 may include a part in contact (for example, direct contact) with the protrusion P of the source/drain region 130 and the second nanosheet N2, and a part in contact (for example, direct contact) with the protrusion P of the source/drain region 130 and the third nanosheet N3.

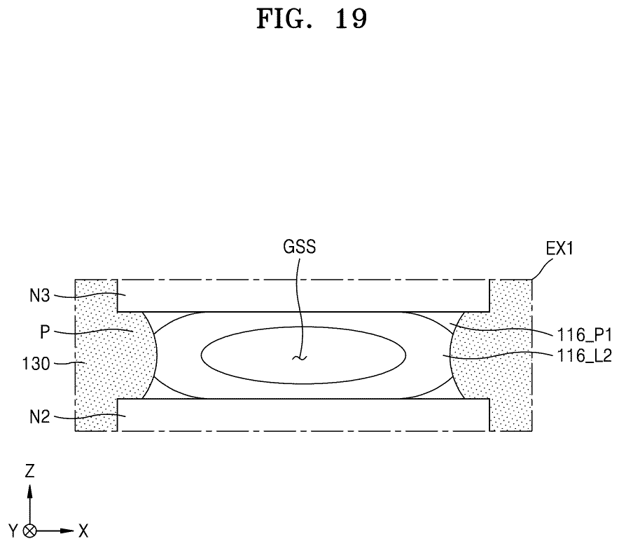

Referring to FIG. 19, a second sub-layer 116_L2 may be formed on the first pre-sub-part 116_P1. For example, the second sub-layer 116_L2 may be formed on the source/drain region 130 and the adjacent nanosheets from among the plurality of nanosheets N1, N2, and N3 on the first pre-sub-part 116_P1. For example, the second sub-layer 116_L2 contacting the protrusion P of the source/drain region 130, the second nanosheet N2, and the third nanosheet N3 may be formed. The second sub-layer 116_L2 may be in contact (for example, direct contact) with the first pre-sub-part 116_P1. For example, the second sub-layer 116_L2 may include silicon oxide, but is not limited thereto.

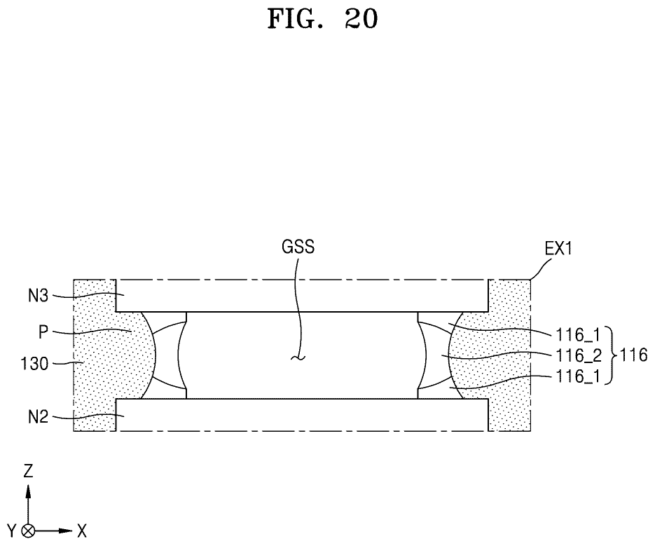

Referring to FIG. 20, a part of the second sub-layer 116_L2 may be removed through the sub-gate space GSS to form a second sub-part 116_2. Similarly, and in some example embodiments at a same or similar time, the first sub-part 116_1 may be formed by removing a part of the first pre-sub-part 116_P1. To form the first sub-part 116_1 and the second sub-part 116_2, etching may be performed by using, for example, dry etching, wet etching, or a combination thereof. Accordingly, the inner insulating spacer 116 including the first sub-part 116_1 and the second sub-part 1162 may be formed.

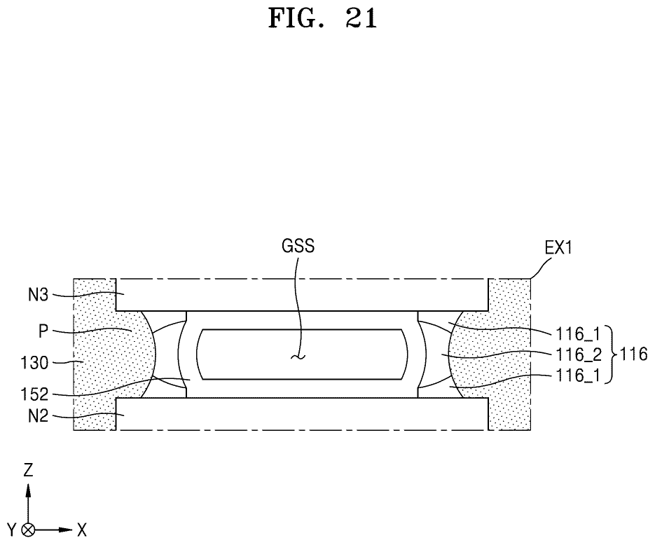

Referring to FIG. 21, a gate dielectric layer 152 may be formed in the sub-gate space GSS. Although not shown, a gate dielectric layer 152 may be formed in the main gate space GSM at the same time. A gate dielectric layer 152 covering a plurality of nanosheets N1, N2, and N3 may be formed in the sub-gate space GSS. An atomic layer deposition (ALD) process may be used to form the gate dielectric layer 152.

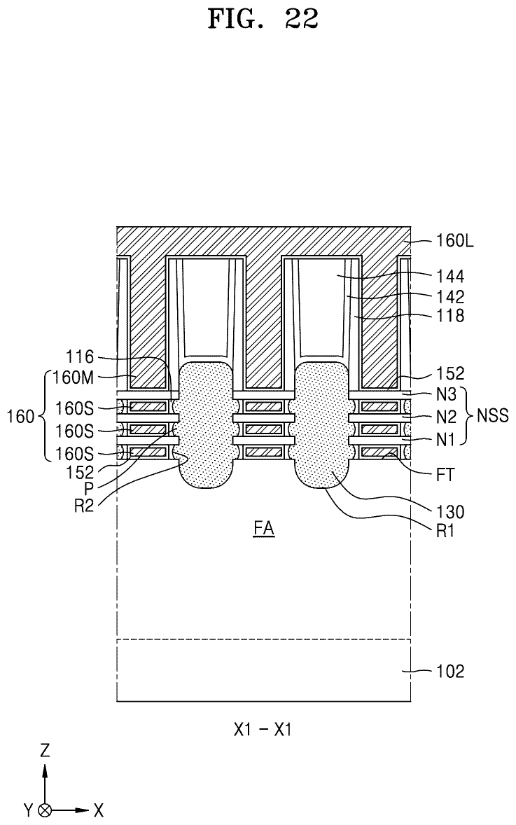

Referring to FIG. 22, a gate-forming conductive layer 160L covering an upper surface of the inter-gate insulating layer 144 while filling the main gate space GSM and the sub-gate space GSS may be formed on the gate dielectric layer 152. The gate forming conductive layer 160L may include for example, one or more a metal, metal nitride, metal carbide, or a combination thereof. An ALD process and/or a CVD process, for example, may be used to form the gate-forming conductive layer 160L, but example embodiments are not limited thereto.

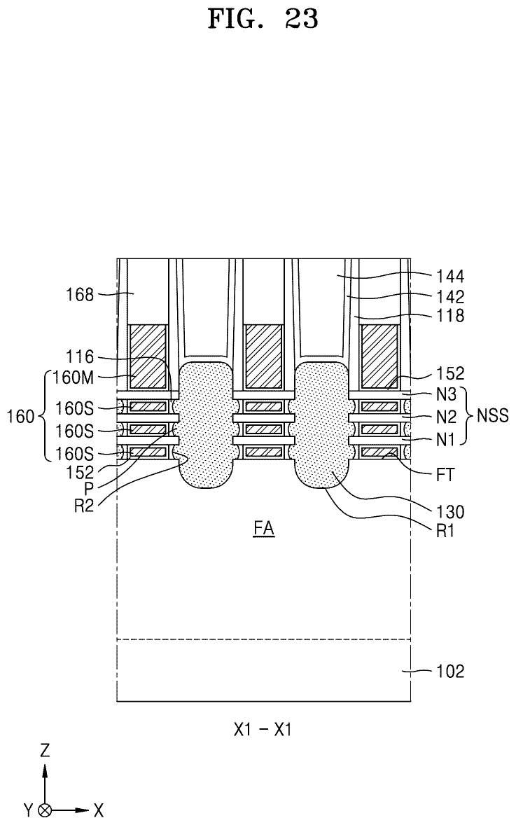

Referring to FIG. 23, the gate forming conductive layer 160L may be partially removed from the upper surface thereof so that the upper surface of the inter-gate insulating layer 144 is exposed and a part of the upper side of the main gate space GSM (see FIG. 13) is emptied again. Accordingly, the plurality of gate lines 160 may be formed from the gate forming conductive layer 160L.

In such case, the gate dielectric layer 152 and the outer insulating spacer 118 in the main gate space GSM may also be partially consumed from the top sides thereof, such that the height of each of the gate dielectric layer 152 and the outer insulating spacer 118 may be lowered. Then, a capping insulating pattern 168 filling the main gate space GSM may be formed on the gate line 160.

Referring back to FIG. 2A, after forming (for example, defining) a source/drain contact hole that penetrates (for example, is defined to extend or at least partially extend through) the insulating structure including the insulating liner 142 and the inter-gate insulating layer 144 to expose the source/drain region 130, a partial region of the source/drain region 130 may be removed through the source/drain contact hole by, for example, a process such as an anisotropic etching process such that the source/drain contact hole may extend longer or further toward the substrate 102. Thereafter, the metal silicide layer 172 may be formed on the source/drain region 130 exposed from the bottom side of the source/drain contact hole. In some example embodiments, in order to form the metal silicide layer 172, a process of forming a metal liner (not shown) covering (for example, conformally covering) an exposed surface of the source/drain region 130 and inducing and/or increasing a reaction between the source/drain region 130 and the metal constituting the metal liner by heat treatment may be included, but example embodiments are not limited thereto. After the metal silicide layer 172 is formed, the remaining portion of the metal liner may be removed. During the process of forming the metal silicide layer 172, a part of the source/drain region 130 may be consumed. In some example embodiments, when the metal silicide layer 172 includes a titanium silicide layer, the metal liner may include, for example, a Ti layer, but example embodiments are not limited thereto.

Thereafter, the source/drain contact CA including the conductive barrier pattern 174 and the contact plug 176 may be formed on the metal silicide layer 172.

Subsequently, an upper insulating structure 180 may be formed on the inter-gate insulating layer 144 and the source/drain contact CA, and a via contact VA may be formed to be connected to the source/drain contact CA through the upper insulating structure 180. Subsequently, the upper insulating layer 192 on the upper insulating structure 180 and the via contact VA and the wiring line M1 penetrating the upper insulating layer 192 may be formed.

Hereinabove, a method of manufacturing the integrated circuit device 100 described with reference to FIGS. 1, 2A to 2C, FIGS. 3, and 4, has been described with reference to FIGS. 11 to 23. However, it will be appreciated by those ordinarily skilled in the art that the integrated circuit devices 100A, 100B, 200, and 200A illustrated in FIGS. 5 to 10 and integrated circuit devices having various modified and changed structures may be manufactured by applying various modifications and changes to the description given with reference to FIGS. 11 to 23 within the spirit and scope of the technical ideas of inventive concepts.

While inventive concepts have been particularly shown and described with reference to example embodiments thereof, it will be understood that various changes in form and details may be made therein without departing from the spirit and scope of the following claims.

What is claimed is:

1. An integrated circuit device comprising:
a fin-type active region on a substrate and extending in a first horizontal direction;
a nanosheet stack including a plurality of nanosheets, the nanosheets facing a fin upper surface of the fin-type active region and spaced apart from the fin upper surface;
a gate line on the fin-type active region, the gate line least partially surrounding each of the plurality of nanosheets and extending in a second horizontal direction intersecting the first horizontal direction, the gate line including a main gate part and a sub-gate part, the main gate part on an upper surface of the nanosheet stack and the sub-gate part between the main gate part and the fin-type active region;
a source/drain region on the fin-type active region, adjacent to the gate line, and in contact with the plurality of nanosheets; and
an inner insulating spacer between the sub-gate part and the source/drain region, wherein
the inner insulating spacer includes a first sub-part in contact with an adjacent nanosheet from among the plurality of nanosheets, and a second sub-part at least partially overlapping with the first sub-part in a vertical direction, and
a first sidewall and a second sidewall of the inner insulating spacer each include a part that is recessed toward an inside of the inner insulating spacer, the first sidewall facing the source/drain and the second sidewall opposite to the first sidewall.

2. The integrated circuit device of claim 1, wherein the inner insulating spacer further comprises:
a third part at least partially overlapping with the first sub-part in the vertical direction and spaced apart from the first sub-part with the second sub-part therebetween,
the first sub-part and the third part comprise a same material, and
the second sub-part comprises a material different from that of the first sub-part and of the third sub-part.

3. The integrated circuit package of claim 2, wherein
the first sub-part and the third part comprise silicon nitride, and
the second sub-part comprises silicon oxide.

4. The integrated circuit device of claim 1, wherein the source/drain region includes a protrusion that protrudes toward the sub-gate part and contacts the first sidewall of the inner insulating spacer.

5. The integrated circuit device of claim 1, wherein the second sub-part is in contact with the source/drain region at the first sidewall.

6. The integrated circuit device of claim 5, wherein a contact area of the first sub-part with the source/drain region is smaller than a contact area of the second sub-part with the source/drain region.

7. The integrated circuit device of claim 1, wherein the second sub-part does not directly contact the adjacent nanosheet from among the plurality of nanosheets.

8. The integrated circuit device of claim 1, wherein the second sub-part includes a part whose vertical thickness increases as the second sub-part is closer to the gate line.

9. The integrated circuit device of claim 1, wherein
an interface between the first sub-part and the second sub-part is in contact with the source/drain region, and
a vertical level of the interface between the first sub-part and the second sub-part is not constant in the first horizontal direction.

10. An integrated circuit device comprising:
a fin-type active region on a substrate and extending in a first horizontal direction,
a channel region on the fin-type active region;
a gate line at least partially surrounding the channel region on the fin-type active region and extending in a second horizontal direction that intersects the first horizontal direction;
a source/drain region on the fin-type active region, adjacent to the gate line, and in contact with the channel region; and
an inner insulating spacer between the gate line and the source/drain region and including a first sidewall, the first sidewall in contact with the source/drain region, wherein
the inner insulating spacer includes two first sub-parts vertically apart from each other and a second sub-part vertically between the two first sub-parts,
the first sidewall of the inner insulating spacer includes a part recessed toward the inside of the inner insulating spacer, and
each of the two first sub-parts includes a part whose vertical thickness decreases as each first sub-part is closer to the gate line.

11. The integrated circuit device of claim 10, wherein
one of the two first sub-parts is in contact with the channel region, and
the second sub-part is in contact with the source/drain region.

12. The integrated circuit device of claim 10, wherein a distance between interfaces of each of the two first sub-parts with respect to the second sub-part increases as each first sub-part is closer to the gate line.

13. The integrated circuit device of claim 10, wherein
the gate line includes a main gate part located at a vertical level higher than the channel region and a sub-gate part between the main gate part and the fin-type active region,
the inner insulating spacer is between the sub-gate part and the source/drain region, and
the sub-gate part includes a part whose width in the first horizontal direction increases and decreases according to vertical level.

14. The integrated circuit device of claim 10, wherein the width of the inner insulating spacer in the first horizontal direction decreases and then increases when moving in a vertical direction.

15. The integrated circuit device of claim 10, wherein a second sidewall of the inner insulating spacer is opposite to the first sidewall and includes a part recessed toward the inside of the inner insulating spacer.

16. The integrated circuit device of claim 10, wherein a contact area of at least one of the two first sub-parts with the source/drain region is smaller than a contact area of the second sub-part with the source/drain region.

17. The integrated circuit device of claim 10, further comprising
a gate insulating layer between the inner insulating spacer and the gate line, wherein
the two first sub-parts of the inner insulating spacer do not directly contact the gate insulating layer.

18. An integrated circuit device comprising:
a fin-type active region on a substrate and extending in a first horizontal direction,
a nanosheet stack including a plurality of nanosheets, at least one the nanosheets facing a fin upper surface of the fin-type active region and spaced apart from the fin upper surface;
a gate line on the fin-type active region, at least partially surrounding each of the plurality of nanosheets, and extending in a second horizontal direction that intersects the first horizontal direction, the gate line including a main gate part on a upper surface of the nanosheet stack and a sub-gate part between the main gate part and the fin-type active region;
a source/drain region on the fin-type active region, adjacent to the gate line, and in contact with the plurality of nanosheets; and
an inner insulating spacer between the sub-gate part and the source/drain region, wherein
the inner insulating spacer includes two first sub-parts vertically apart from each other, and a second sub-part vertically between the two first sub-parts,
the two first sub-parts comprise silicon nitride, the second sub-part comprises silicon oxide,
a first sidewall and second sidewall of the inner insulating spacer each include a part that is recessed toward the inside of the inner insulating spacer, the first sidewall in contact with the source/drain and the second sidewall opposite to the first sidewall, and
a distance between interfaces of each of the two first sub-parts with respect to the second sub-part increases as each first sub-part is closer to the gate line.

19. The integrated circuit device of claim 18, wherein the source/drain region includes a protrusion that protrudes toward the sub-gate part and contacts the first sidewall of the inner insulating spacer.

20. The integrated circuit device of claim 18, wherein
at least a part of each of the two first sub-parts is in contact with the source/drain region,
at least a part of the second sub-part is in contact with the source/drain region at the first sidewall, and
a contact area of each of the two first sub-parts with the source/drain region is smaller than a contact area of the second sub-part with the source/drain region.
